(19) United States
(12) Patent Application Publication
(10) Pub. No.: US 2026/0013101 A1
(43) Pub. Date: Jan. 8, 2026

(54) SEMICONDUCTOR DEVICE AND METHOD FOR FABRICATING THE SAME

(71) Applicant: SK hynix Inc., Gyeonggi-do (KR)

(72) Inventors: Gil Seop KIM, Gyeonggi-do (KR); Jae Sun SONG, Gyeonggi-do (KR)

(21) Appl. No.: 19/014,229

(22) Filed: Jan. 9, 2025

(30) Foreign Application Priority Data
Jul. 8, 2024 (KR) 10-2024-0089608

(51) Int. Cl. H10B 12/00

(52) U.S. Cl. CPC H10B 12/30; H10B 12/03; H10B 12/05

(57) ABSTRACT

A semiconductor device may include a first conductive line vertically oriented in a first direction; a data storage element horizontally spaced apart from the first conductive line; a nano sheet horizontally oriented in a second direction perpendicular to the first direction, and including a first sheet region contacting the first conductive line and a second sheet region contacting the data storage element, which has a thickness gradually increasing from the first sheet region toward the data storage element; and a second conductive line extending while surrounding the nano sheet in a third direction perpendicular to the first and second directions.

### CROSS-REFERENCE TO RELATED APPLICATIONS

The present application claims priority under 35 U.S.C. 119(a) to Korean Patent Application No. 10-2024-0089608, filed on Jul. 8, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the large capacity and miniaturization of a memory device, a three-dimensional (3D) memory device in which a plurality of memory cells are stacked has been proposed.

### SUMMARY

Embodiments of the present disclosure are directed to a semiconductor device including high-integrated memory cells, and a method for fabricating the semiconductor device.

In accordance with an embodiment of the present disclosure, a semiconductor device may include a first conductive line vertically oriented in a first direction; a data storage element horizontally spaced apart from the first conductive line; a nano sheet horizontally oriented in a second direction perpendicular to the first direction, and including a first sheet region contacting the first conductive line and a second sheet region contacting the data storage element, which has a thickness gradually increasing from the first sheet region toward the data storage element; and a second conductive line extending while surrounding the nano sheet in a third direction perpendicular to the first and second directions.

In accordance with an embodiment of the present disclosure, a semiconductor device may include a first conductive line vertically oriented in a first direction; a data storage element horizontally spaced apart from the first conductive line; a nano sheet horizontally oriented in a second direction perpendicular to the first direction, and including a first doped region, a second doped region, and a channel between the first doped region and the second doped region, the first doped region contacting the first conductive line, the second doped region contacting the data storage element and having a thickness gradually increasing from the first doped region toward the data storage element; and a second conductive line extending while surrounding the channel of the nano sheet in a third direction perpendicular to the first and second directions.

In accordance with an embodiment of the present disclosure, a semiconductor device may include a first conductive line vertically oriented in a first direction; a data storage element horizontally spaced apart from the first conductive line; a nano sheet horizontally oriented in a second direction perpendicular to the first direction, and including a first doped region, a second doped region, and a channel between the first doped region and the second doped region, the first doped region contacting the first conductive line, the second doped region contacting the data storage element and having a thickness gradually increasing from the first doped region toward the data storage element; a second conductive line extending while surrounding the channel of the nano sheet in a third direction perpendicular to the first and second directions; and a contact node including a selective epitaxial growth layer between the second doped region of the nano sheet and the data storage element.

In accordance with an embodiment of the present disclosure, a semiconductor device may include a vertical stack including a column array of nano sheet transistors vertically stacked in a first direction, wherein each of the nano sheet transistors includes a flat plate-shaped sheet, a fan-shaped sheet having a horizontal length less than the flat plate-shaped sheet; a nano sheet extending in a second direction perpendicular to the first direction; and a horizontal conductive line extending in a third direction perpendicular to the first and second directions while surrounding the flat plate-shaped sheet.

In accordance with an embodiment of the present disclosure, a semiconductor device may include a first column array of nano sheet transistors vertically stacked in a first direction; a second column array of nano sheet transistors horizontally spaced apart from the first column array and vertically stacked in the first direction; a vertical conductive line extending in the first direction while sharing the nano sheet transistors of the first column array and the nano sheet transistors of the second column array; and data storage elements respectively coupled to the nano sheet transistors of the first and second column arrays. Each of the nano sheet transistors includes a flat plate-shaped sheet, a fan-shaped sheet having a horizontal length less than the flat plate-shaped sheet; a nano sheet extending in a second direction perpendicular to the first direction; and a horizontal conductive line extending in a third direction perpendicular to the first and second directions while surrounding the flat plate-shaped sheet.

In accordance with an embodiment of the present disclosure, a method for fabricating a semiconductor device may include forming nano sheet target layers over a substrate, the nano sheet target layers vertically stacked and spaced apart from each other; forming flat plate-shaped sheets that trim first portions of the nano sheet target layers; horizontally recessing second portions of the nano sheet target layers to form fan-shaped sheets; selectively growing contact nodes on side surfaces of the fan-shaped sheets; and forming data storage elements coupled to the contact nodes.

In accordance with an embodiment of the present disclosure, a method for fabricating a semiconductor device may include forming nano sheet target layers over a substrate, the nano sheet target layers vertically stacked and spaced apart from each other; forming flat plate-shaped sheets that trim first portions of the nano sheet target layers; forming horizontal conductive lines extending while surrounding the flat plate-shaped sheets disposed at the same horizontal level; forming first contact nodes respectively coupled to the flat plate-shaped sheets; forming a vertical conductive line coupled to the first contact nodes; horizontally recessing second portions of the nano sheet target layers to form fan-shaped sheets; selectively growing second contact nodes on side surfaces of the fan-shaped sheets; and forming data storage elements respectively coupled to the second contact nodes.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view illustrating the memory cell illustrated in FIG. 1A.

FIG. 2A is a schematic view illustrating a semiconductor device in accordance with an embodiment of the present disclosure.

FIG. 2B is a schematic perspective view illustrating a memory cell array illustrated in FIG. 2A.

FIG. 2C is an equivalent circuit view illustrating a column array illustrated in FIG. 2B.

FIG. 2D is an equivalent circuit view illustrating a row array illustrated in FIG. 2B.

FIG. 3 is a schematic plan view illustrating a semiconductor device in accordance with an embodiment of the present disclosure.

FIG. 4A is a cross-sectional view illustrating the semiconductor device taken along line A-A′ illustrated in FIG. 3.

FIG. 4B is a cross-sectional view illustrating the semiconductor device taken along line B-B′ illustrated in FIG. 3.

FIGS. 5A to 23B illustrate various views of a semiconductor device formed utilizing a method for fabricating the semiconductor device in accordance with an embodiment of the present disclosure.

FIGS. 24A to 28B illustrate various views of a semiconductor device formed utilizing a method for fabricating the semiconductor device in accordance with an embodiment of the present disclosure.

FIGS. 29A and 29B are schematic cross-sectional views illustrating a semiconductor device in accordance with embodiments of the present disclosure.

FIGS. 30A and 30B illustrate various views illustrating a stack assembly in accordance with an embodiment of the present disclosure.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The present disclosure is not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the disclosure.

The following embodiment relates to three-dimensional memory cells, in which memory cells are vertically stacked to increase memory cell density and reduce parasitic capacitance.

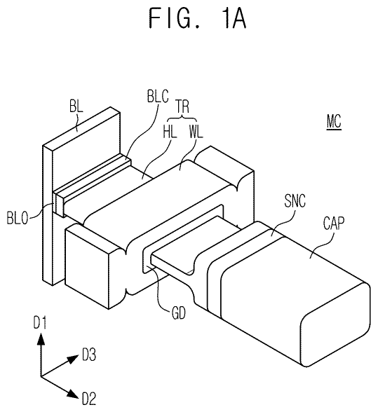

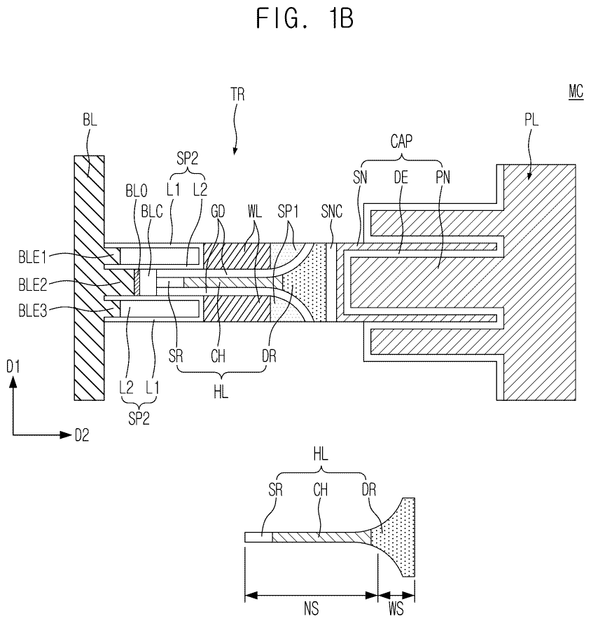

FIG. 1A is a schematic perspective view illustrating a memory cell MC in accordance with an embodiment of the present disclosure. FIG. 1B is a schematic cross-sectional view illustrating the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertical-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR has a function of controlling voltage or current supply to the data storage element CAP during a data write operation and a data read operation performed on the data storage element CAP. The switching element TR may include a nano sheet HL, a nano sheet dielectric layer GD, and a second conductive line WL. The second conductive line WL may include a horizontal conductive line or a horizontal word line. The nano sheet HL may include an active layer. The switching element TR may include a transistor, and in this case, the second conductive line WL may serve as a gate electrode. The switching element TR may also be referred to as a “nano sheet transistor”, an “access element” or a “selection element”. The second conductive line WL may be referred to as a “horizontal gate electrode” or a “horizontal word line”.

The nano sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2. The second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be coupled to the first conductive line BL, and the second doped region DR may be coupled to the data storage element CAP. The height of the second doped region DR in the first direction D1 may be greater than that of the channel CH in the first direction D1. The length of the second doped region DR in the second direction D2 may be less than that of the channel CH in the second direction D2. The lengths of the first doped region SR, the channel CH and the second doped region DR in the third direction D3 may be equal to one another.

The nano sheet HL may include a first region NS and a second region WS that are horizontally disposed in the second direction D2. The second region WS may extend from the first region NS. The second region WS may have a thickness that gradually increases in the second direction D2 from the first region NS toward the data storage element CAP, between the first region NS and the data storage element CAP. An average vertical height or thickness of the second region WS in the first direction D1 may be greater than that of the first region NS. Hereinafter, the first region NS is referred to as a “narrow sheet” or “a first sheet region”, and the second region WS is referred to as a “wide sheet” or “a second sheet region”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, and the second doped region DR may be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thin portion disposed in the narrow sheet NS. One side of the wide sheet WS contacting the data storage element CAP and one side of the second doped region DR may each have a flat side shape.

A horizontal length of the wide sheet WS in the second direction D2 may be less than that of the narrow sheet NS. The narrow sheet NS may be referred to as a “long sheet”, and the wide sheet WS may be referred to as a “short sheet”.

The nano sheet HL may include a semiconductor material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include conductive metal oxide. In some embodiments, the nano sheet HL may include a two-dimensional material, for example, MoS₂, WS₂, or MoSe₂.

When the nano sheet HL is formed of the oxide semiconductor material, the channel CH may also be formed of the oxide semiconductor material, and the first and second doped regions SR and DR may be omitted. The nano sheet HL may also be referred to as an “active layer” or a “thin body”.

The first doped region SR and the second doped region DR may be doped with the same conductivity type of impurities. The first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as “first and second source/drain regions”.

The nano sheet HL may be horizontally oriented in the second direction D2 from the first conductive line BL.

The second conductive line WL may have a gate all around structure (GAA) surrounding the nano sheet HL. For example, the second conductive line WL may surround the channel CH of the nano sheet HL and extend in the third direction D3. A nano sheet dielectric layer GD may be formed between the nano sheet HL and the second conductive line WL. The nano sheet dielectric layer GD may surround the nano sheet HL. The second conductive line WL may surround the nano sheet HL on the nano sheet dielectric layer GD.

The second conductive line WL may include a metal-based material, a semiconductor material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or lower, and the P-type work function material may have a high work function of approximately 4.5 eV or higher. The second conductive line WL may include a stack of a low work function material and a high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by a thermal oxidation process of a semiconductor material.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1. The horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL.

The data storage element CAP may have a three-dimensional structure. The first electrode SN may have a three-dimensional structure, and the first electrode SN having the three-dimensional structure may have a horizontal three-dimensional structure that is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces of the first electrode SN.

In some embodiments, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a titanium silicon nitride/titanium nitride (TiSiN/TiN) stack, or a combination thereof. The second electrode PN may also include a combination of a metal-based material and a silicon-based material.

For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material. Alternatively, the dielectric layer DE may have a laminated structure or an intermixed structure. In the laminated structure, a plurality of high-k materials and a plurality of high band gap materials are stacked. In the intermixed structure, a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, an interface control layer may be further formed between the first electrode SN and the dielectric layer DE to improve leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductor material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano sheet HL and the first electrode SN. The second contact node SNC may include a metal-based material or a semiconductor material. For example, the second contact node SNC may include titanium, titanium nitride, tungsten, or a combination thereof. In addition, the second contact node SNC may include doped polysilicon, and the second doped region DR may include an impurity diffused from the second contact node SNC. The height of the first contact node BLC in the first direction D1 may be less than that of the second contact node SNC in the first direction D1. The height of the first contact node BLC in the first direction D1 may be greater than that of the channel CH in the first direction D1.

The nano sheet HL may include a first edge portion and a second edge portion. The first edge portion may refer to a portion of the first doped region SR electrically coupled to the first conductive line BL. The second edge portion may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a stack of a first liner L1 and a second liner L2. The first and second spacers SP1 and SP2 may each include a dielectric material. The first and second spacers SP1 and SP2 may each include silicon oxide, silicon nitride, or a combination thereof. The first spacer SP1 may include silicon nitride. The first liner L1 of the second spacer SP2 may be silicon nitride, whereas the second liner L2 may be silicon oxide. The second liner L2 may partially fill an inner space of the first liner L1. The first spacer SP1 and the second spacer SP2 may surround the horizontal arrangement of nano sheets HL along the third direction D3.

The first conductive line BL may include a plurality of horizontal extension portions BLE1, BLE2, and BLE3. The horizontal extension portions BLE1, BLE2, and BLE3 may extend in the second direction D2. The horizontal extension portions BLE1, BLE2, and BLE3 may include an inner horizontal extension portion BLE2 and outer horizontal extension portions BLE1 and BLE3. The inner horizontal extension portion BLE2 of the first conductive line BL may extend to be disposed in a gap between the first liners L1 vertically adjacent to each other. Accordingly, the inner horizontal extension portion BLE2 of the first conductive line BL may be electrically coupled to the ohmic contact layer BLO.

The outer horizontal portions BLE1 and BLE3 of the first conductive line BL may extend to be disposed in one side of the second spacer SP2. Accordingly, the outer horizontal portions BLE1 and BLE3 of the first conductive line BL may contact the second liner L2 of the second spacer SP2.

In an embodiment, the second contact node SNC may be selectively grown from the wide sheet WS of the nano sheet HL. The second contact node SNC may be formed by selective epitaxial growth (SEG). For example, the second contact node SNC may be a silicon epitaxial layer formed by selective epitaxial growth (SEG). The second contact node SNC may be a doped silicon epitaxial layer.

In some embodiments, the first contact node BLC may also be selectively grown from the narrow sheet NS of the nano sheet HL. The first contact node BLC may be formed by selective epitaxial growth (SEG). For example, the first contact node BLC may be a silicon epitaxial layer formed by selective epitaxial growth (SEG). The first contact node BLC may be a doped silicon epitaxial layer.

The first contact node BLC may be a narrow sheet-side contact node, whereas the second contact node SNC may be a wide sheet-side contact node.

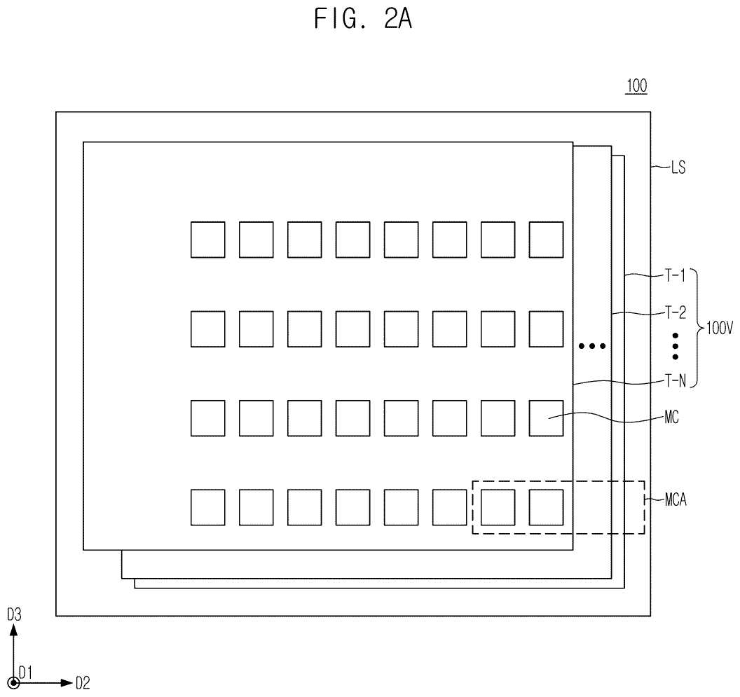

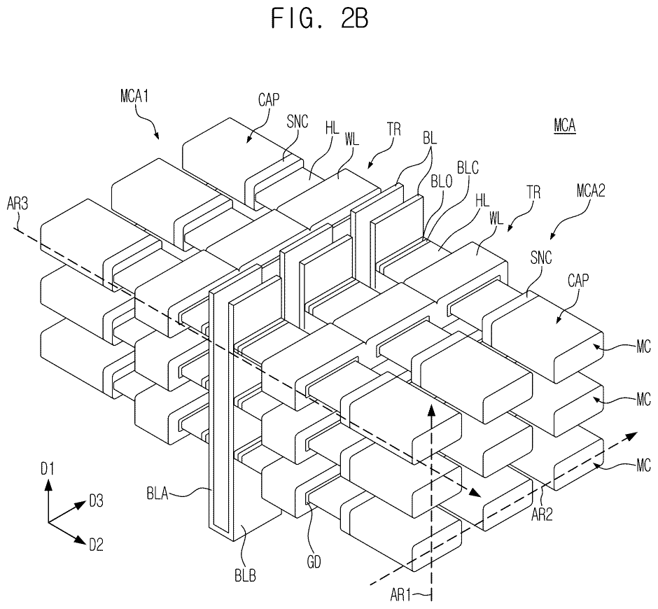

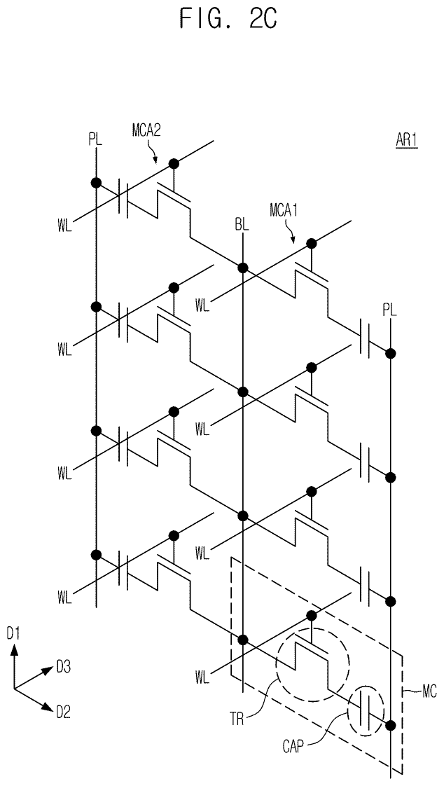

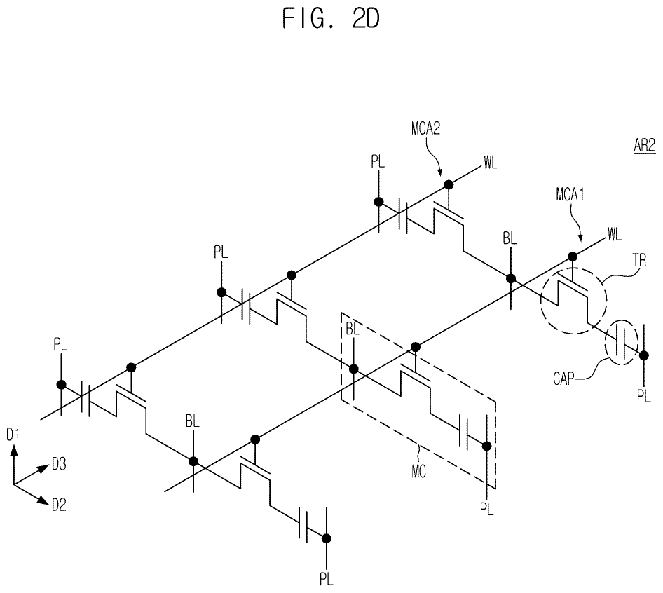

FIG. 2A is a schematic view illustrating a semiconductor device 100 in accordance with an embodiment of the present disclosure. FIG. 2B is a schematic perspective view illustrating a memory cell array MCA illustrated in FIG. 2A. FIG. 2C is an equivalent circuit view illustrating a column array AR1 illustrated in FIG. 2B. FIG. 2D is an equivalent circuit view illustrating a row array AR2 illustrated in FIG. 2B.

Referring to FIG. 2A, the semiconductor device 100 may include a plurality of planes T−1 to T−N. The planes T−1 to T−N may constitute a vertical stack 100V. Each of the planes T−1 to T−N may include a plurality of memory cells MC. The vertical stack 100V may include a memory cell array MCA. The memory cell array MCA may include a three-dimensional array of the memory cells MC. Detailed components of the memory cells MC are described above with reference to FIGS. 1A and 1B.

Referring to FIGS. 2B to 2D, the memory cell array MCA may include the plurality of memory cells MC vertically stacked in a first direction D1. The memory cell array MCA may include the plurality of memory cells MC horizontally disposed in a second direction D2. The memory cell array MCA may include the plurality of memory cells MC horizontally disposed in a third direction D3.

Each of the memory cells MC may include a first conductive line BL, a switching element TR, and a data storage element CAP. The switching element TR may include a second conductive line WL, a nano sheet dielectric layer GD, and a nano sheet HL.

The memory cell array MCA may include a column array AR1 of the memory cells MC and a row array AR2 of the memory cells MC. The column array AR1 may include the plurality of memory cells MC vertically stacked in a first direction D1. The memory cells MC of the column array AR1 may share the first conductive line BL. The row array AR2 may include the plurality of memory cells MC horizontally disposed in a third direction D3. The memory cells MC of the row array AR2 may share the second conductive line WL. The first direction D1 may be a vertical direction, and the third direction D3 may be a horizontal direction. The memory cell array MCA may further include a horizontal level array AR3. The horizontal level array AR3 may include the plurality of memory cells MC disposed at the same horizontal level in a second direction D2. Neighboring memory cells MC of the horizontal level array AR3 may share the first conductive line BL.

The memory cell array MCA may include a first sub-cell array MCA1 and a second sub-cell array MCA2. The first sub-cell array MCA1 and the second sub-cell array MCA2 may each include a three-dimensional array of the memory cells MC. The first sub-cell array MCA1 and the second sub-cell array MCA2 may share the first conductive line BL. The first conductive line BL may include a first vertical conductive line BLA and a second vertical conductive line BLB. A bottom portion of the first vertical conductive line BLA and a bottom portion of the second vertical conductive line BLB may be merged with each other. The first conductive line BL may have a U-shape formed by merging the first vertical conductive line BLA and the second vertical conductive line BLB. The memory cells MC of the first sub-cell array MCA1 may share the first vertical conductive line BLA, and the memory cells MC of the second sub-cell array MCA2 may share the second vertical conductive line BLB. In this way, the neighboring first and second sub-cell arrays MCA1 and MCA2 may have a mirror-type structure sharing the first conductive line BL. From the perspective of a top view, the first and second vertical conductive lines BLA and BLB may each have a rectangular shape.

Referring back to FIG. 2A, a lower structure LS may be disposed at a lower level than the memory cell array MCA. The lower structure LS may include a semiconductor substrate, a metal interconnection structure, a dielectric structure, a conductive structure, a bonding pad structure, another memory, or a peripheral circuit portion. For example, the lower structure LS may include a structure in which the peripheral circuit portion, the metal interconnection structure, and the bonding pad structure are sequentially stacked. The memory cell array MCA and the peripheral circuit portion of the lower structure LS may be bonded by wafer bonding. The wafer bonding may include pad bonding, hybrid bonding, oxide-to-oxide bonding, metal-to-metal bonding, or a combination thereof.

The peripheral circuit portion of the lower structure LS may be disposed at a lower level than the memory cell array MCA. This may be referred to as a “cell array over PERI (COP) structure” or a “PERI under cell array (PUC) structure”. The peripheral circuit portion may include at least one control circuit for driving the memory cell array MCA. At least one control circuit of the peripheral circuit portion may include an N-channel transistor, a P-channel transistor, a CMOS circuit, or a combination thereof. At least one control circuit of the peripheral circuit portion may include an address decoder circuit, a read circuit, or a write circuit. At least one control circuit of the peripheral circuit portion may include a planar channel transistor, a recess channel transistor, a buried gate transistor, or a fin channel transistor (FinFET).

For example, the peripheral circuit portion may include sub-word line drivers and a sense amplifier. The first conductive line BL may be coupled to the sense amplifier, whereas the second conductive lines DWL may be coupled to the sub-word line drivers.

In some embodiments, the peripheral circuit portion may be disposed at a higher level than the memory cell array MCA. This may be referred to as a “PERI over cell (POC) structure” or a “cell array under PERI (CUP) structure”.

In some embodiments, the memory cell array MCA may include DRAM, embedded DRAM, NAND, FeRAM, STT-RAM, PCRAM, or ReRAM.

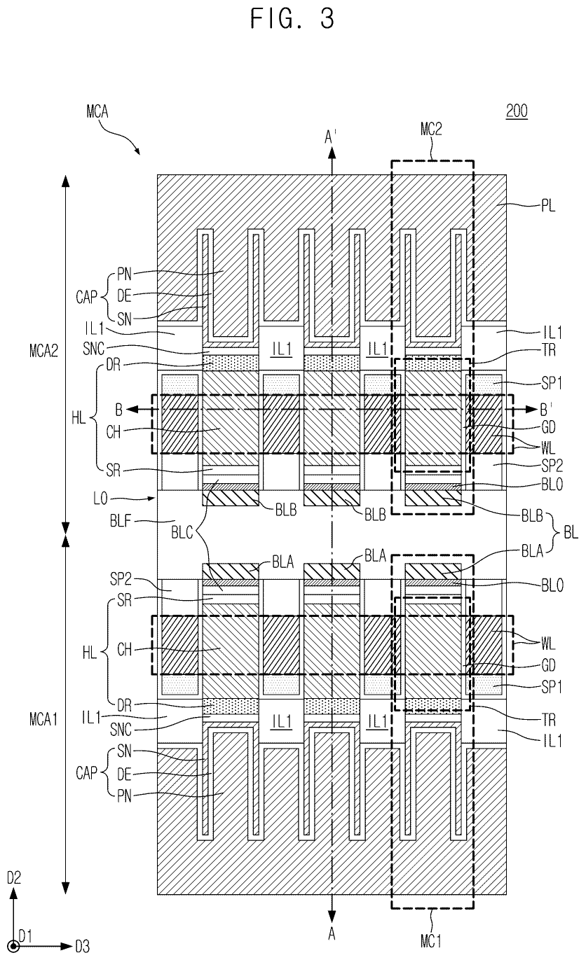

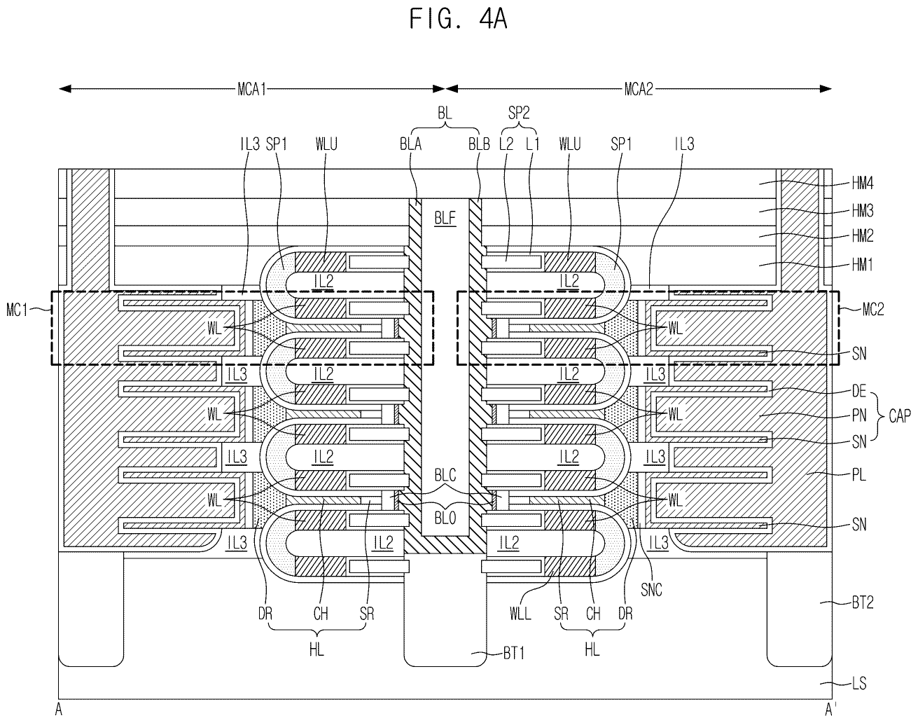

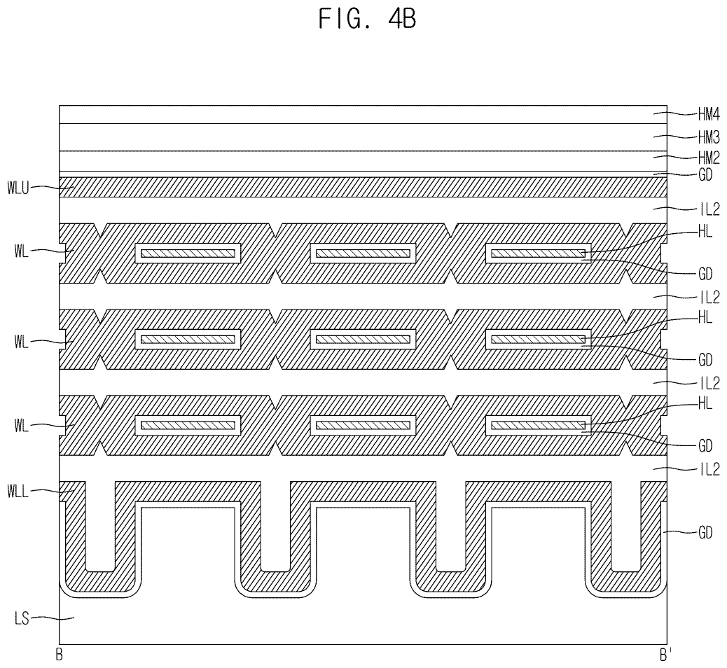

FIG. 3 is a schematic plan view illustrating a semiconductor device 200 in accordance with an embodiment of the present disclosure. FIG. 3 may be a plan view illustrating the semiconductor device 200 to describe an example of the row array AR2 illustrated in FIG. 2B. FIG. 4A is a cross-sectional view illustrating the semiconductor device 200 taken along line A-A′ illustrated in FIG. 3. FIG. 4B is a cross-sectional view illustrating the semiconductor device 200 taken along line B-B′ illustrated in FIG. 3.

The semiconductor device 200 illustrated in FIGS. 3 to 4B may be similar to the memory cell array MCA illustrated in FIGS. 2A to 2D. Hereinafter, detailed descriptions of overlapping components are omitted.

Referring to FIGS. 3, 4A and 4B, the semiconductor device 200 may include a memory cell array MCA. The memory cell array MCA may include a three-dimensional array of memory cells MC1 and MC2. The memory cell array MCA may include a first sub-cell array MCA1 and a second sub-cell array MCA2.

The memory cell array MCA may include a plurality of memory cells MC1 and MC2 vertically stacked in a first direction D1. Each of the memory cells MC1 and MC2 may have the same configuration as the memory cell MC described with reference to FIGS. 1A and 1B. The memory cell array MCA may include the plurality of memory cells MC1 and MC2 horizontally disposed in a second direction D2. The memory cell array MCA may include the plurality of memory cells MC1 and MC2 horizontally disposed in a third direction D3. The memory cell array MCA may include a plurality of first conductive lines BL. Each of the first conductive lines BL may include a first vertical conductive line BLA and a second vertical conductive line BLB. A bottom portion of the first vertical conductive line BLA and a bottom portion of the second vertical conductive line BLB may be merged with each other.

A first memory cell MC1 of the first sub-cell array MCA1 may include the first vertical conductive line BLA, a switching element TR, and a data storage element CAP. The switching element TR of the first memory cell MC1 may include a second conductive line WL and a nano sheet HL. A second memory cell MC2 of the second sub-cell array MCA2 may include the second vertical conductive line BLB, a switching element TR, and a data storage element CAP. The switching element TR of the second memory cell MC2 may include a second conductive line WL and a nano sheet HL. The switching elements TR of the first and second memory cells MC1 and MC2 may be nano sheet transistors.

The first conductive lines BL may vertically extend in the first direction D1. The nano sheet HL may extend in the second direction D2. The second conductive line WL may horizontally extend in the third direction D3.

First inter-cell dielectric layers IL1 may be disposed between the data storage elements CAP disposed adjacent to each other in the third direction D3. Second inter-cell dielectric layers IL2 may be disposed between the second conductive lines WL vertically stacked in the first direction D1. Third inter-cell dielectric layers IL3 may be disposed between first electrodes SN of the data storage elements CAP vertically stacked in the first direction D1. The first to third inter-cell dielectric layers IL1, IL2, and IL3 may each include silicon oxide, silicon carbon oxide (SiCO), silicon nitride, or a combination thereof. The first inter-cell dielectric layers IL1 may be referred to as “device isolation layers” or “cell isolation layers”.

Each of the memory cells MC1 and MC2 may further include a first contact node BLC and a second contact node SNC. The first contact node BLC may be disposed between the first conductive line (BLA and BLB) and the nano sheet HL. The first contact node BLC may include a metal-based material or a semiconductor material. For example, the first contact node BLC may include titanium, titanium nitride, tungsten, or a combination thereof. In addition, the first contact node BLC may include doped polysilicon, and a first doped region SR may include an impurity diffused from the first contact node BLC. The second contact node SNC may be disposed between the nano sheet HL and the first electrode SN. The second contact node SNC may include a metal-based material or a semiconductor material. For example, the second contact node SNC may include titanium, titanium nitride, tungsten, or a combination thereof. In addition, the second contact node SNC may include doped polysilicon, and a second doped region DR may include an impurity diffused from the second contact node SNC. A height of the first contact node BLC in the first direction D1 may be less than a height of the second contact node SNC in the first direction D1. A height of the first contact node BLC in the first direction D1 may be greater than a height of a channel CH in the first direction D1.

Each of the memory cells MC1 and MC2 may further include an ohmic contact layer BLO between the first contact node BLC and the first conductive line BL. The ohmic contact layer BLO may include metal silicide.

Each of the memory cells MC1 and MC2 may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a stack of a first liner L1 and a second liner L2. The first and second spacers SP1 and SP2 may each include a dielectric material. The first and second spacers SP1 and SP2 may each include silicon oxide, silicon nitride, or a combination thereof. The first spacer SP1 may include silicon nitride. The first liner L1 of the second spacer SP2 may be silicon nitride, and the second liner L2 of the second spacer SP2 may be silicon oxide. The first spacer SP1 may cover one side of the second inter-cell dielectric layers IL2. The first spacer SP1 may have a cup shape, for example, a “,” shape.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first conductive lines BL spaced apart in the third direction D3. The memory cell array MCA may include dummy second conductive lines WLU disposed at a level higher than an uppermost-level second conductive line WL, and dummy second conductive lines WLL at a level lower than a lowermost-level second conductive line WL. The dummy second conductive lines WLU and WLL may each have a linear shape extending horizontally.

The memory cell array MCA may include a stack of a plurality of hard mask layers HM1, HM2, HM3, and HM4 disposed at a level higher than the uppermost-level second conductive line WL.

The memory cell array MCA may include a plurality of first and second bottom passivation layers BT1 and BT2. The first bottom passivation layer BT1 may prevent the bottom surface of the first conductive line BL and the lower structure LS from coming into electrical contact with each other. The second bottom passivation layer BT2 may prevent the data storage element CAP and the lower structure LS from coming into electrical contact with each other.

A vertical isolation layer BLF may be disposed between the first vertical conductive line BLA and the second vertical conductive line BLB of the first conductive line BL. The vertical isolation layer BLF may include a dielectric material.

The nano sheets HL of the switching elements TR horizontally disposed in the third direction D3 may share one second conductive line WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to a common plate PL.

In an embodiment, the semiconductor device 200 may include a column array and a row array of the nano sheets HL, the second conductive lines WL surrounding in common the nano sheets HL of the row array and each surrounding the nano sheets HL of the column array, the data storage elements CAP coupled to the nano sheets HL of the column array and the row array, respectively, and the first conductive lines BL coupled in common to the nano sheets HL of the column array. Each of the first conductive lines BL may include the first vertical conductive line BLA and the second vertical conductive line BLB. The first vertical conductive line BLA and the second vertical conductive line BLB may be formed through a mask and etching process.

From another perspective, the semiconductor device 200 may include the first sub-cell array MCA1, the second sub-cell array MCA2, a linear opening (refer to reference symbol “LO” in FIG. 3), and the first conductive line BL. The first sub-cell array MCA1 includes the first memory cells MC1 vertically stacked. The second sub-cell array MCA2 includes the second memory cells MC2 vertically stacked. The linear opening (refer to reference symbol “LO” in FIG. 3) is disposed between the first sub-cell array MCA1 and the second sub-cell array MCA2. The first conductive line BL is formed in the linear opening LO and electrically coupled to the first and second memory cells MC1 and MC2 horizontally disposed adjacent to each other.

From another perspective, the semiconductor device 200 may include the first conductive line BL vertically oriented in the first direction D1, the data storage element CAP horizontally spaced apart from the first conductive line BL, the nano sheets HL, and the second conductive line WL. The nano sheets HL include the nano sheet HL horizontally oriented in the second direction D2 perpendicular to the first direction D1, and the nano sheet HL including the first region NS contacting the first conductive line BL and the second region WS contacting the data storage element CAP. The second conductive line WL is extending while surrounding the nano sheet HL in the third direction D3 perpendicular to the first and second directions D1 and D3.

From another perspective, the semiconductor device 200 may include a vertical stack including the column array AR1 of nano sheet transistors TR vertically stacked in the first direction D1. Each of the nano sheet transistors TR may include a flat plate-shaped narrow sheet NS and a fan-shaped wide sheet WS having a horizontal length less than the flat plate-shaped narrow sheet NS. Each of the nano sheet transistors TR may further include the nano sheet HL extending in the second direction D2 perpendicular to the first direction D1, and the second conductive line WL surrounding the flat plate-shaped narrow sheet NS and horizontally oriented in the third direction D3 perpendicular to the first and second directions D1 and D2.

From another perspective, the semiconductor device 200 may include a first column array MCA1 of nano sheet transistors TR vertically stacked in the first direction D1, a second column array MCA2 of the nano sheet transistors TR horizontally spaced apart from the first column array MCA1 and vertically stacked in the first direction D1, the vertical conductive line BL sharing the nano sheet transistors TR of the first column array MCA1 and the nano sheet transistors TR of the second column array MCA2 and extending in the first direction D1, and the data storage elements CAP coupled to the nano sheet transistors TR of the first and second column arrays MCA1 and MCA2. Each of the nano sheet transistors TR may include a flat plate-shaped narrow sheet NS and a fan-shaped wide sheet WS having a horizontal length less than the flat plate-shaped narrow sheet NS. Each of the nano sheet transistors TR may further include the nano sheet HL extending in the second direction D2 perpendicular to the first direction D1, and the second conductive line WL surrounding the flat plate-shaped narrow sheet NS and horizontally oriented in the third direction D3 perpendicular to the first and second directions D1 and D2.

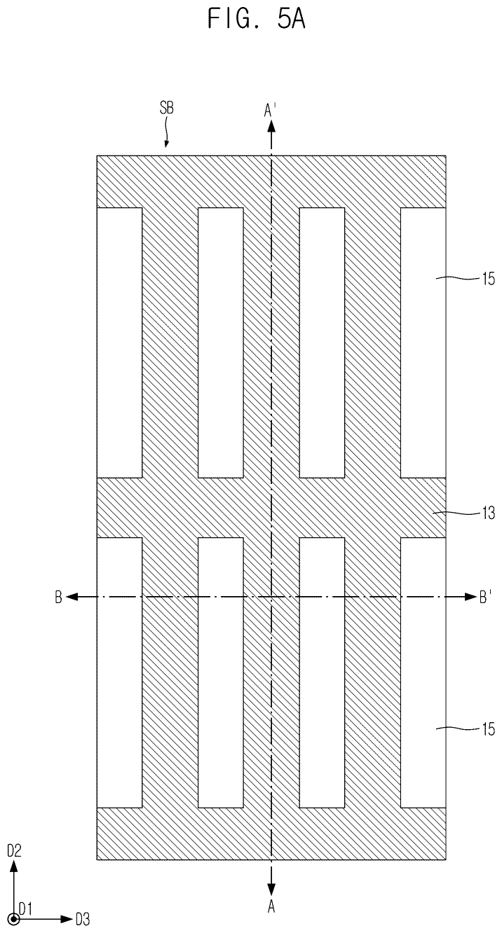

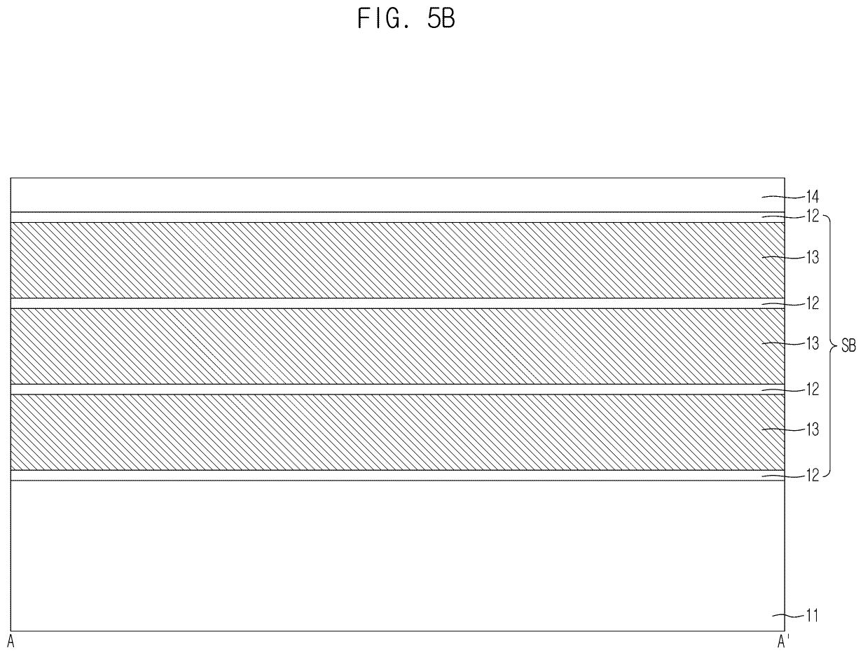

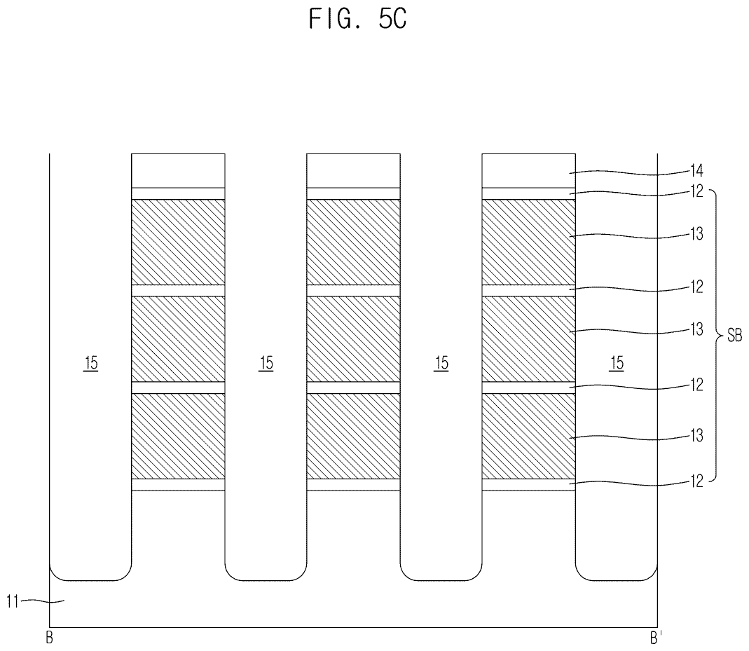

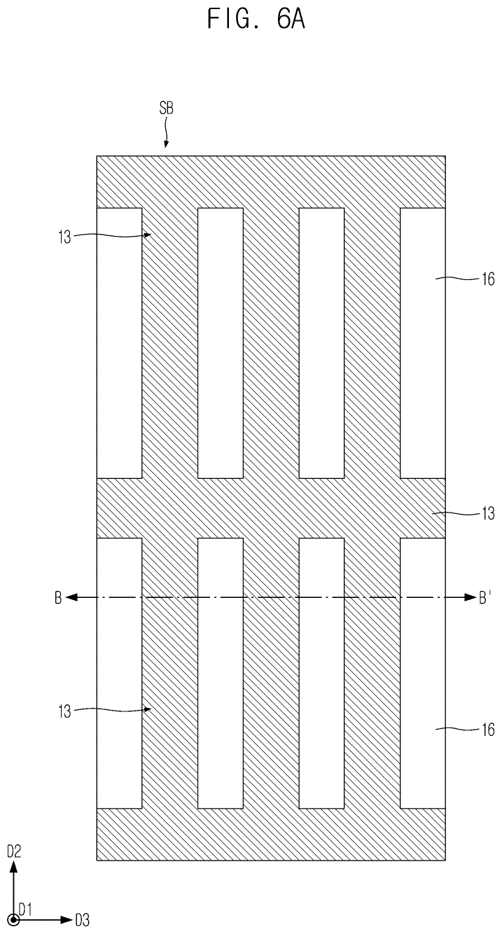

FIGS. 5A to 23B illustrate various views of a semiconductor device formed utilizing a method for fabricating the semiconductor device in accordance with an embodiment of the present disclosure.

FIG. 5A is a plan view illustrating a structure at a second mold layer level to describe a method for forming a mold stack SB. FIG. 5B is a cross-sectional view illustrating the structure taken along line A-A′ illustrated in FIG. 5A. FIG. 5C is a cross-sectional view illustrating the structure taken along line B-B′ illustrated in FIG. 5A.

Referring to FIGS. 5A to 5C, the mold stack SB may be formed on a substrate 11. The mold stack SB may include an alternating stack of first mold layers 12 and second mold layers 13.

In order to form the mold stack SB, the first mold layers 12 may be alternately stacked with the second mold layers 13, and the first mold layers 12 and the second mold layers 13 may be epitaxially grown multiple times. Alternating layers of the first mold layer 12 and the second mold layer 13 may be repeatedly grown to form multi-level tiers such as a first tier, a second tier, a third tier, . . . , and an N^{th} tier in the mold stack SB. Each tier may include a two-layer structure of the first mold layer 12 and the second mold layer 13. The first mold layer 12 may be disposed at the top of the mold stack SB.

The first mold layers 12 and the second mold layers 13 may be different semiconductor materials. Each of the first mold layers 12 may include silicon germanium or monocrystalline silicon germanium. Each of the second mold layers 13 may include monocrystalline silicon. The first mold layers 12 and the second mold layers 13 may be formed by an epitaxial growth process. The lowermost first mold layer 12 may serve as a seed layer during the epitaxial growth process. Each of the first mold layers 12 may be thinner than each of the second mold layers 13. The first mold layers 12 may include first epitaxially grown layers, and the second mold layers 13 may include second epitaxially grown layers.

In one embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer/a monocrystalline silicon layer (a SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the first mold layers 12 and the second mold layers 13 in the mold stack SB may be variously modified. For example, the thickness of the first mold layers 12 may be approximately 5 to 20 nm, and the thickness of the second mold layers 13 may be approximately 50 to 80 nm. The quantity of layers of the first mold layers 12 and the second mold layers 13 in the mold stack SB may be variously modified. In some embodiments, a triple stack including the first mold layer 12, the second mold layer 13, and the first mold layer 12 may be defined at the lowermost and/or uppermost portions of the mold stack SB. The second mold layer 13 of the triple stack may have a thickness less than the second mold layer 13 of the mold stack SB.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include SiO₂, Si₃N₄, amorphous carbon, or a combination thereof.

Subsequently, portions of the mold stack SB may be etched using the first hard mask layer 14 as a barrier so that a plurality of sacrificial isolation openings 15 may be formed. The sacrificial isolation openings 15 may be initial openings for cell isolation. From the perspective of a top view, cross-sections of the sacrificial isolation openings 15 may each have a rectangular shape. In some embodiments, the cross-sections of the sacrificial isolation openings 15 may each have a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3. The bottom surfaces of the sacrificial isolation openings 15 may extend into the inside of the substrate 11.

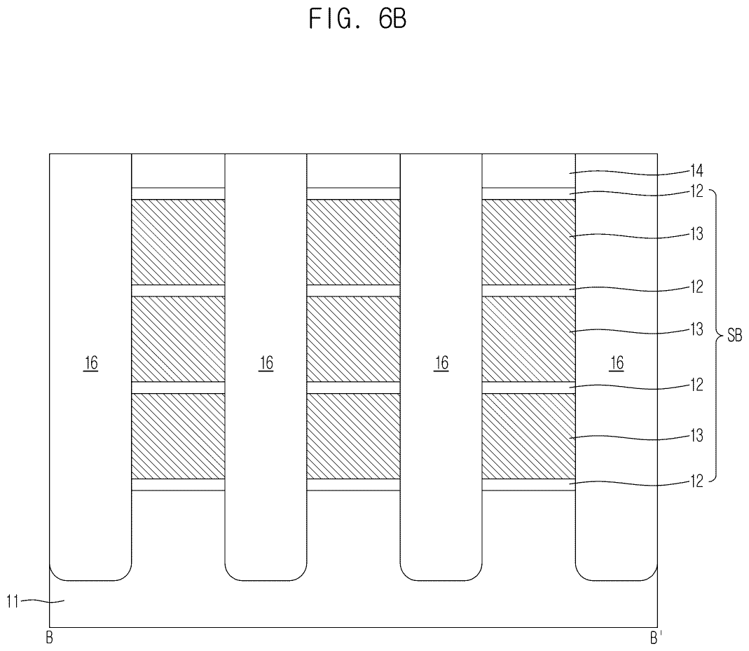

FIG. 6A is a plan view illustrating the structure at the second mold layer level to describe a method for forming sacrificial isolation layers 16, and FIG. 6B is a cross-sectional view illustrating the structure taken along line B-B′ illustrated in FIG. 6A.

Referring to FIGS. 6A and 6B, the sacrificial isolation layers 16 may be formed to fill the sacrificial isolation openings 15 of FIGS. 5A and 5C. The sacrificial isolation layers 16 may include the same material. The sacrificial isolation layers 16 may be formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the mold stack SB to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3. Each of the sacrificial isolation layers 16 may include a stack of a first sacrificial liner layer and a first sacrificial gap-fill layer. The first sacrificial liner layer may be silicon nitride, and the first sacrificial gap-fill layer may be silicon oxide. The sacrificial isolation layers 16 may penetrate the stack body SB in the first direction D1.

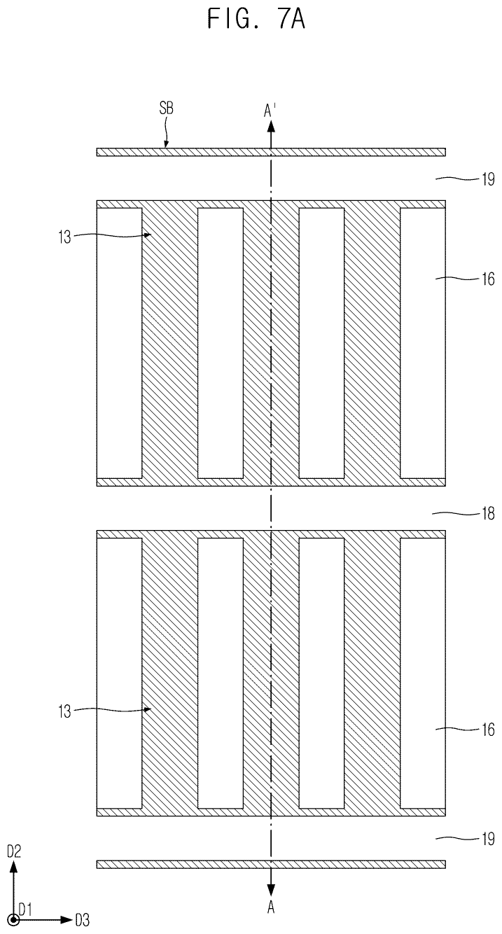

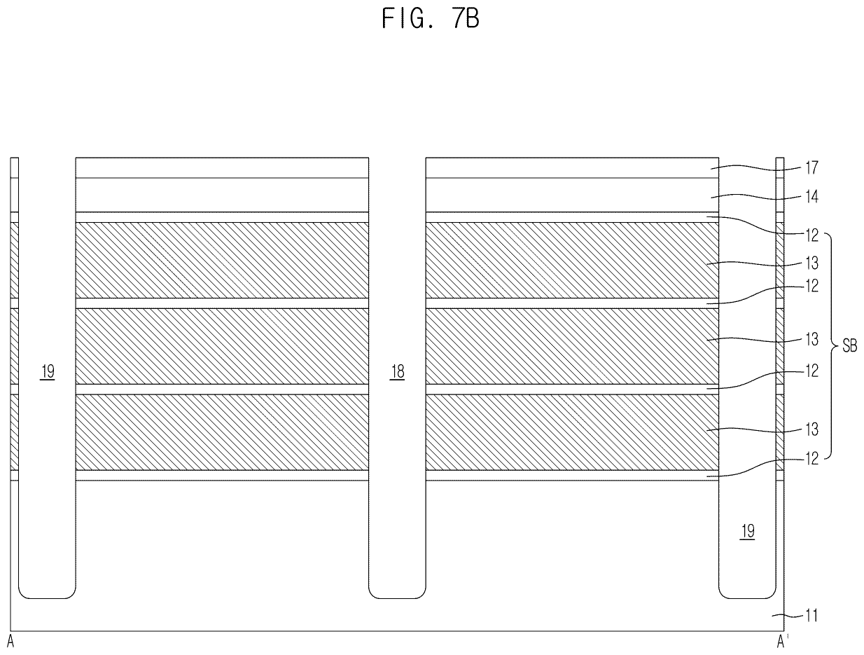

FIG. 7A is a plan view illustrating the structure at the second mold layer level to describe a method for forming sacrificial linear openings 18 and 19, and FIG. 7B is a cross-sectional view illustrating the structure taken along line A-A′ illustrated in FIG. 7A.

Referring to FIGS. 7A and 7B, a second hard mask layer 17 may be formed on the mold stack SB and the sacrificial isolation layers 16. The second hard mask layer 17 may include silicon nitride. The second hard mask layer 17 may be formed by etching a second hard mask material using a mask layer such as photoresist. The second hard mask layer 17 may have a plurality of line-shaped openings defined therein.

Portions of the mold stack SB may be etched using the second hard mask layer 17 as an etching barrier. Accordingly, a plurality of sacrificial linear openings 18 and 19 may be formed between the sacrificial isolation layers 16. The sacrificial linear openings may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The sacrificial isolation layers 16 may be disposed between the first sacrificial linear opening 18 and the second sacrificial linear opening 19 in the second direction D2. From the perspective of a top view, cross sections of the first and second sacrificial linear openings 18 and 19 may each have a rectangular shape. In some embodiments, the cross sections of the first and second sacrificial linear openings 18 and 19 may each have a circular shape or oval shape. The first and second sacrificial linear openings 18 and 19 may each have a width in the second direction D2 which is less than a width in the third direction D3. The first and second sacrificial linear openings 18 and 19 may be referred to as “sacrificial linear trenches”. The sacrificial isolation layers 16 may not contact the first and second sacrificial linear openings 18 and 19.

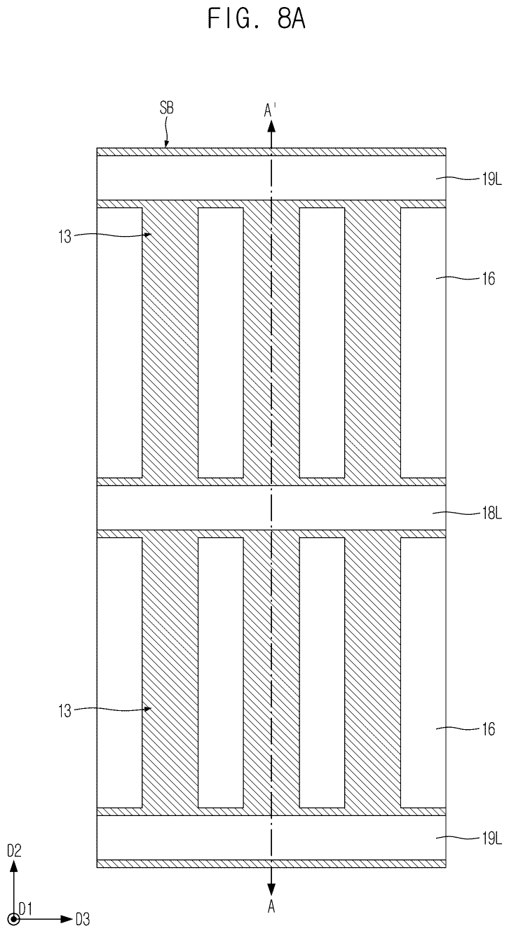

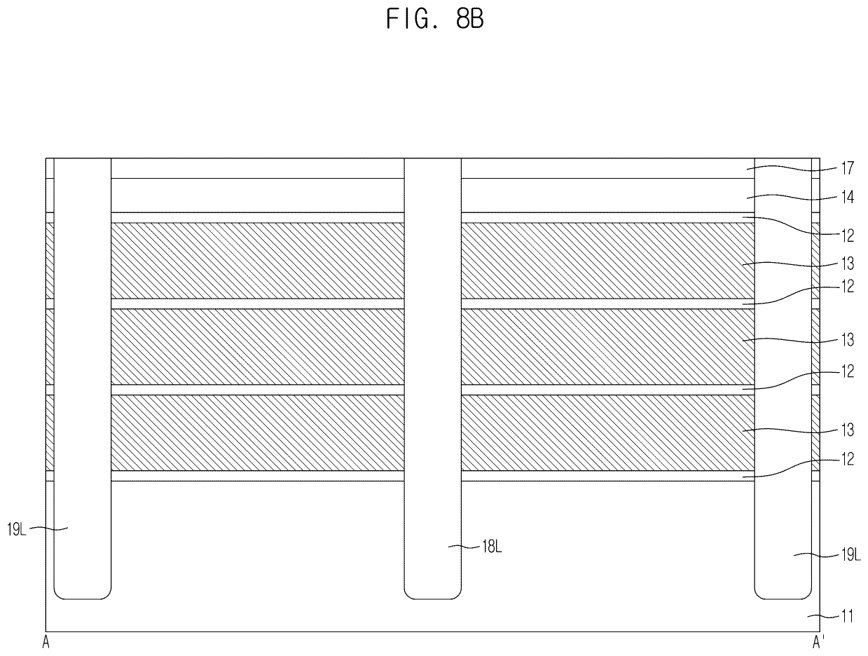

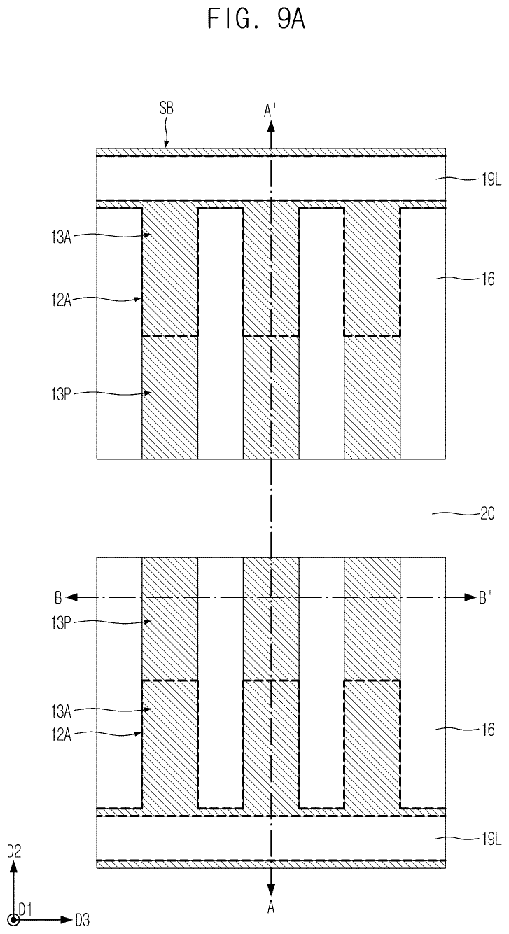

FIG. 8A is a plan view illustrating the structure at the second mold layer level to describe a method for forming linear sacrificial layers 18L and 19L, and FIG. 8B is a cross-sectional view illustrating the structure taken along line A-A′ illustrated in FIG. 8A.

Referring to FIGS. 8A and 8B, the linear sacrificial layers 18L and 19L may be formed to fill the first and second sacrificial linear openings 18 and 19 of FIGS. 7A and 7B. The linear sacrificial layers may include a first linear sacrificial layer 18L and a second linear sacrificial layer 19L. From the perspective of a top view, the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a circular shape or an oval shape. The first and second linear sacrificial layers 18L and 19L may include the same material. The first and second linear sacrificial layers 18L and 19L may be formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact the first and second linear sacrificial layers 18L and 19L.

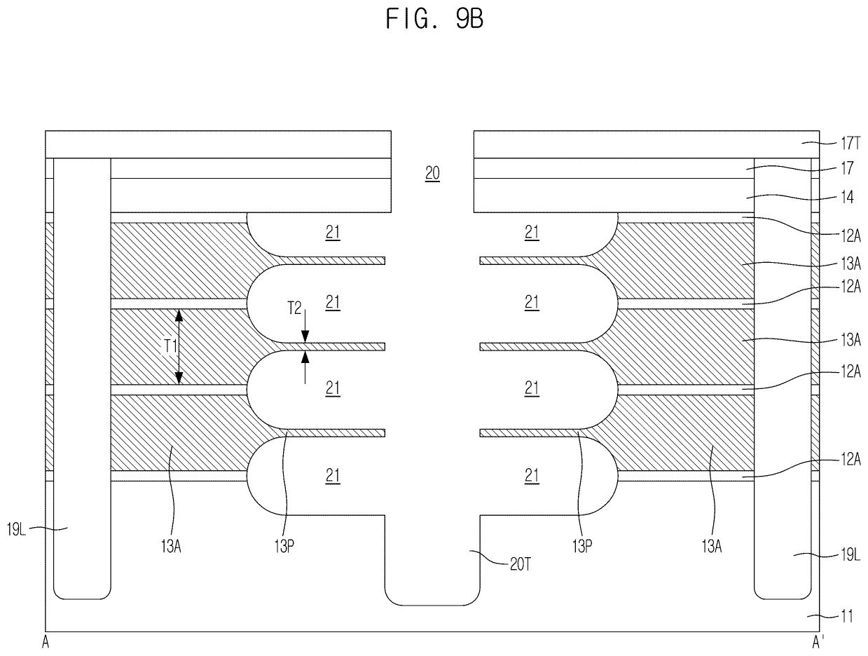

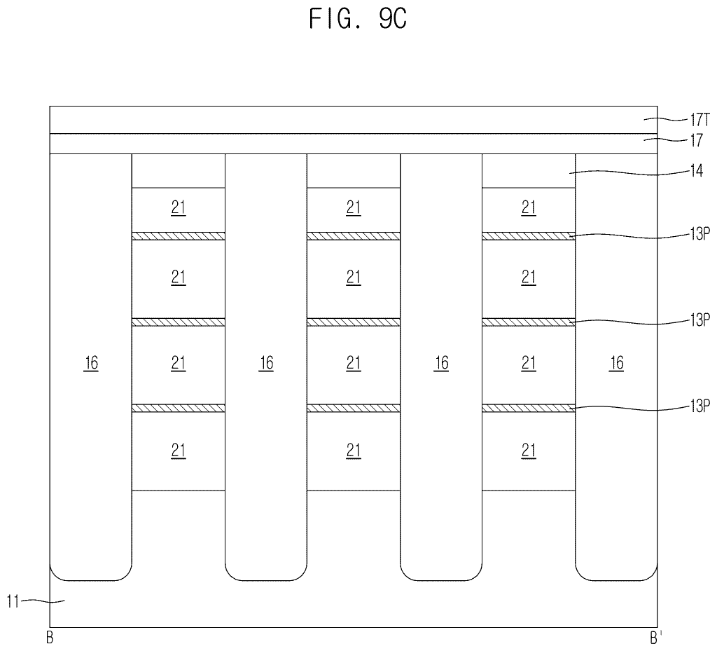

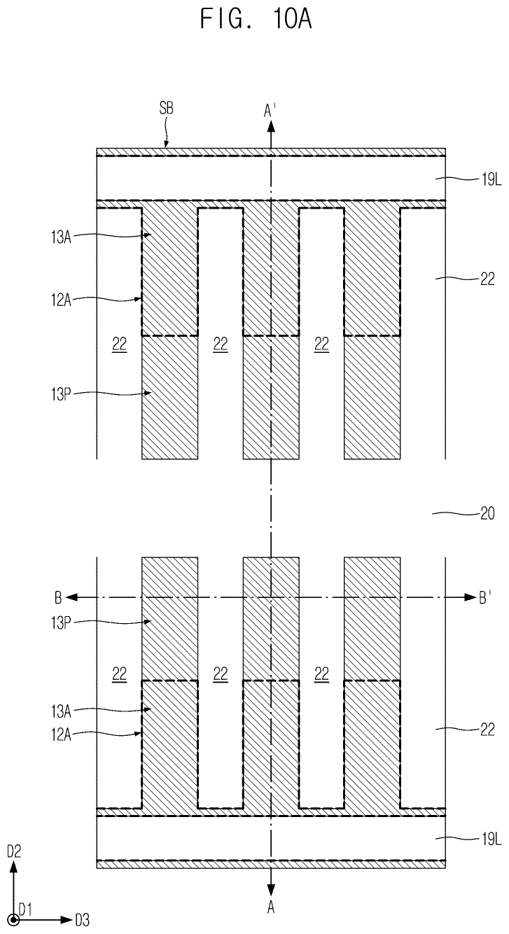

FIG. 9A is a plan view illustrating the structure at the second mold layer level to describe recessing of the second mold layers 13, and FIG. 9B is a cross-sectional view illustrating the structure taken along line A-A′ illustrated in FIG. 9A. FIG. 9C is a cross-sectional view illustrating the structure taken along line B-B′ illustrated in FIG. 9A.

Referring to FIGS. 9A to 9C, among the first linear sacrificial layer 18L and the second linear sacrificial layer 19L, the first linear sacrificial layer 18L may be selectively removed. A third hard mask layer 17T may be used as an etching barrier to remove the first linear sacrificial layer 18L. Accordingly, a first linear opening 20 may be formed. From the perspective of a top view, the first linear opening 20 may be disposed horizontally spaced apart from the second linear sacrificial layer 19L in the second direction D2.

The first linear opening 20 may have the same size as a size greater than the first sacrificial linear opening 18 described with reference to FIG. 7A. A bottom surface of a bottom portion 20T of the first linear opening 20 may be at the same level as a bottom surface of the first sacrificial linear opening 18. The bottom surface of the first linear opening 20 may be at the same level as the bottom surface of the sacrificial isolation layer 16.

The first mold layers 12 and the second mold layers 13 may be selectively recessed through the first linear openings 20.

First, in order to selectively recess the first mold layers 12, the difference in etch selectivity between the first mold layers 12 and the second mold layers 13 may be used. The first mold layers 12 may be removed using a wet etch process or a dry etch process. For example, when the first mold layers 12 include silicon germanium layers and the second mold layers 13 include monocrystalline silicon layers, the silicon germanium layers may be etched using an etchant or etching gas having a selectivity with respect to the monocrystalline silicon layers. The first mold layers having an original thickness may remain as indicated by reference numeral “12A”.

Subsequently, portions (first portions) of the second mold layers 13 may be recessed to form narrow sheets 13P. The wet etch process or dry etch process may be used to recess the second mold layers 13. Original body portions 13A and the narrow sheets 13P may be formed by the partial recessing of the second mold layers 13. The original body portions 13A may each maintain an original thickness T1, and the narrow sheets 13P may each have a thickness T2 less than the original thickness T1. Horizontal lengths of the original body portions 13A in the second direction D2 may be equal to or different from horizontal lengths of the and the narrow sheets 13P in the second direction D2. The combination of each original body portion 13A and each narrow sheet 13P may be referred to as a “preliminary active layer”. The narrow sheets 13P may be referred to as “flat plate-shaped sheets” or “protruding narrow sheets”.

The recess process for forming the narrow sheets 13P may be referred to as a “thinning process” or “trimming process” of the second mold layers 13. In order to form the narrow sheets 13P, upper surfaces, lower surfaces and side surfaces of the second mold layers 13 may be recessed. The narrow sheets 13P may be referred to as “thin-body active layers”. The narrow sheets 13P may each include a monocrystalline silicon layer. The recess process for forming the narrow sheets 13P may use, for example, Hot SC-1 (HSC1). The HSC1 may include a solution in which ammonium hydroxide (NH₄OH), hydrogen peroxide (H₂O₂), and water (H₂O) are mixed in a ratio of 1:4:20. Using the HSC1, the second mold layers 13 may be selectively etched.

The narrow sheets 13P may be formed by the partial recess process for the second mold layers 13 as described above, and inter-nano sheet recesses 21 may be formed between the narrow sheets 13P that are vertically disposed. Upper and lower surfaces of the narrow sheets 13P may each include a flat surface. A boundary portion between each original body portion 13A and each narrow sheet 13P may be vertical or have a curvature. Each first mold layer 12A may be disposed between two original body portions 13A that are vertically stacked.

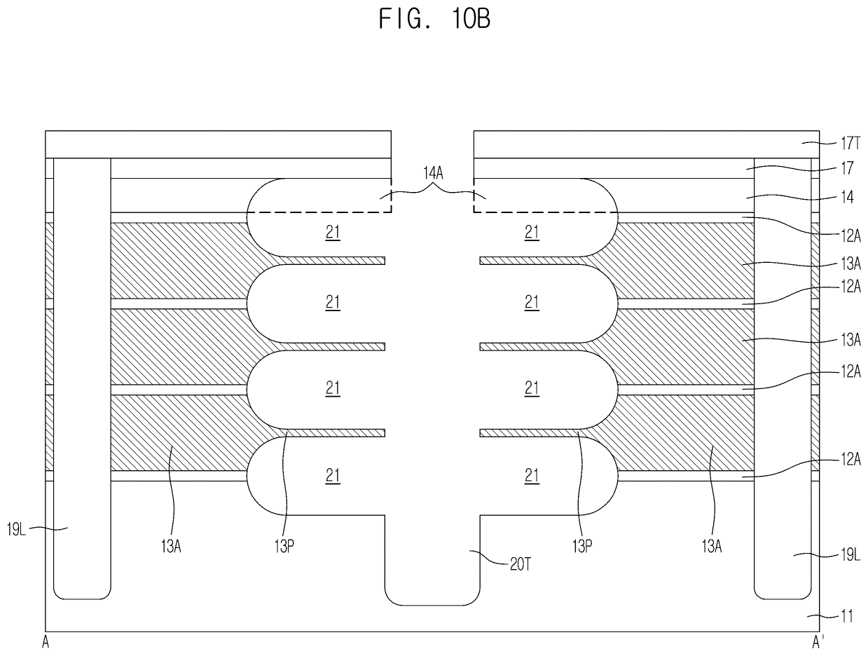

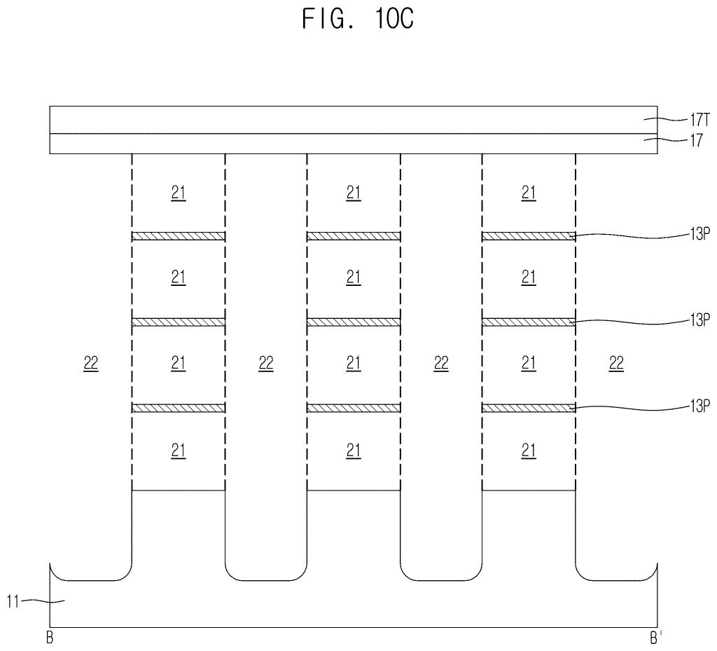

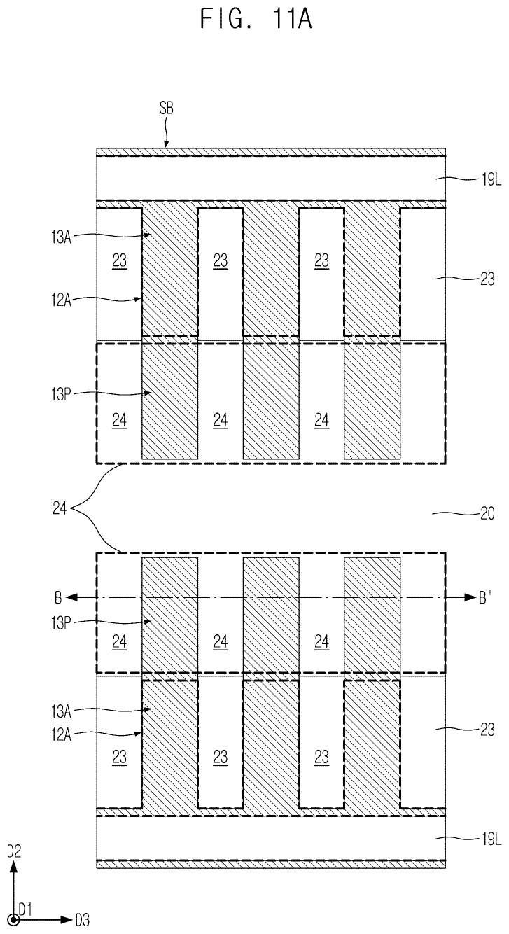

FIG. 10A is a plan view illustrating the structure at a narrow sheet level to describe a method for forming sacrificial isolation layer-level openings 22, and FIG. 10B is a cross-sectional view illustrating the structure taken along line A-A′ illustrated in FIG. 10A. FIG. 10C is a cross-sectional view illustrating the structure taken along line B-B′ illustrated in FIG. 10A.

Referring to FIGS. 10A to 10C, the sacrificial isolation layers 16 of FIGS. 9A and 9C may be selectively stripped through the inter-nano sheet recesses 21. Accordingly, the sacrificial isolation layer-level openings 22 may be formed between the original body portions 13A in the third direction D3.

Side surfaces of the first mold layers 12A, side surfaces of the original body portions 13A, and side surfaces of the narrow sheets 13P may be exposed in the third direction D3 by the sacrificial isolation layer-level openings 22.

While the sacrificial isolation layer-level openings 22 are formed, a portion of the first hard mask layer 14 (refer to reference numeral “14A” of FIG. 10B) may be recessed. Accordingly, a space of the inter-nano sheet recess 21 at the uppermost level may be expanded.

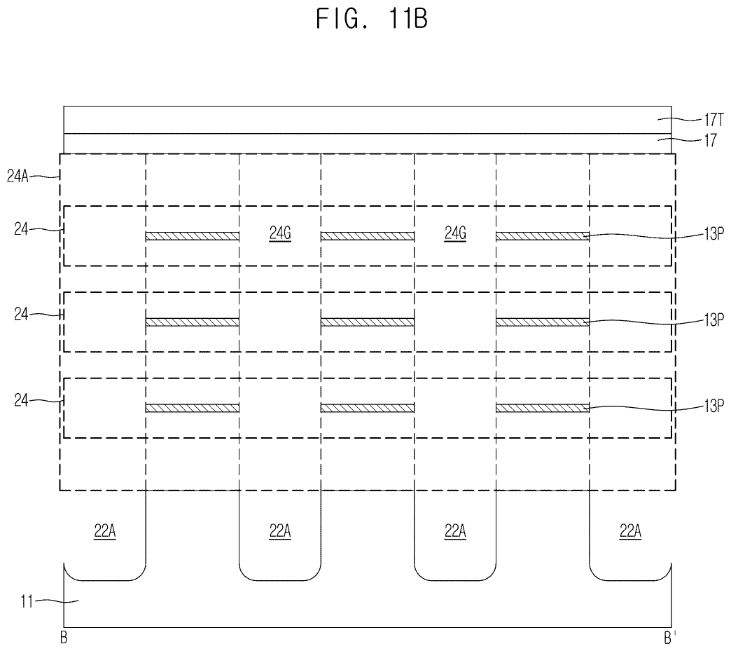

FIG. 11A is a plan view illustrating the structure at the narrow sheet level to describe a method for forming first inter-cell dielectric layers 23. FIG. 11B is a cross-sectional view illustrating the structure taken along line B-B′ illustrated in FIG. 11A.

Referring to FIGS. 11A and 11B, the first inter-cell dielectric layers 23 may be formed in the sacrificial isolation layer-level openings 22. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material.

The first inter-cell dielectric layers 23 may fill portions of the sacrificial isolation layer-level openings 22. The side surfaces of the first mold layers 12A and the side surfaces of the original body portions 13A may be covered by the first inter-cell dielectric layers 23 in the third direction D3. The first inter-cell dielectric layers 23 may expose the side surfaces of the narrow sheets 13P. The other portions of the sacrificial isolation layer-level openings 22, i.e., non-gap-filled portion 22A, may expose the side surfaces of the narrow sheets 13P.

After the first inter-cell dielectric layers 23 are formed, a nano sheet all-open recess 24A that opens all of the narrow sheets 13P may be formed. The nano sheet all-open recess 24A may refer to a combination of the inter-nano sheet recesses 21 and the non-gap-filled portions 22A of the sacrificial isolation layer-level openings 22. The nano sheet all-open recess 24A may include a plurality of surrounding recesses 24. The surrounding recesses 24 may expose all of the narrow sheets 13P in the third direction D3. For example, one of the surrounding recesses 24 extending in the third direction D3 may surround all surfaces of the narrow sheets 13P at the same horizontal level.

Each of the surrounding recesses 24 may include a plurality of initial gaps 24G. The initial gaps 24G may be included between the narrow sheets 13P in the third direction D3.

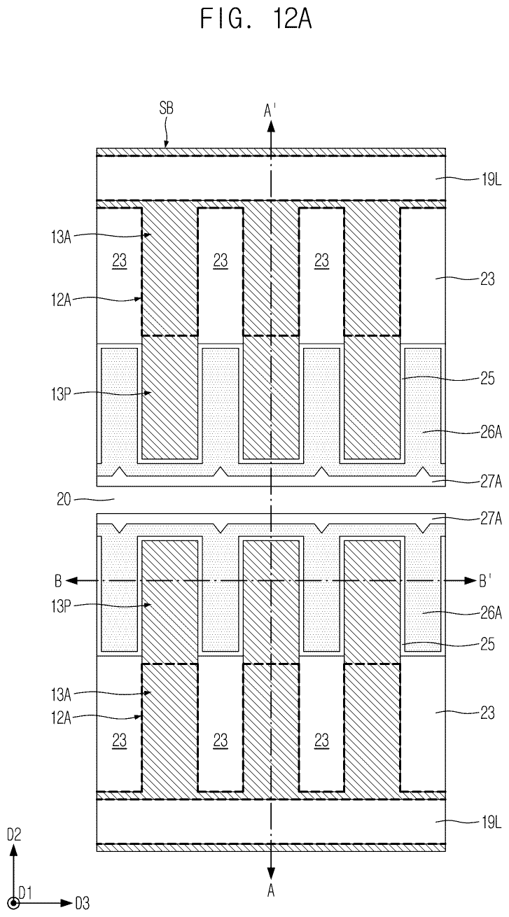

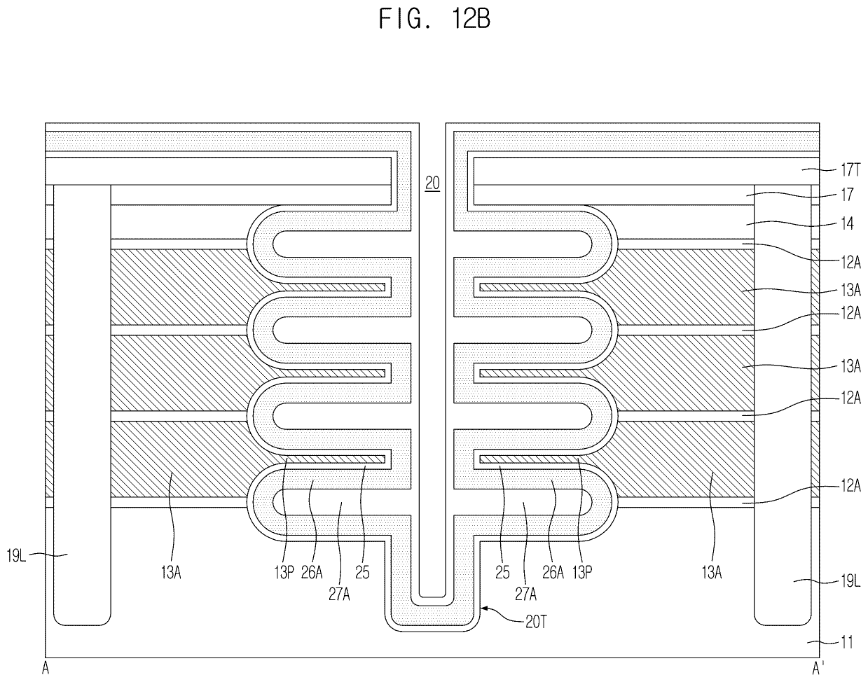

FIG. 12A is a plan view illustrating the structure at the narrow sheet level to describe a method for forming a first spacer layer 26A. FIG. 12B is a cross-sectional view illustrating the structure taken along line A-A′ illustrated in FIG. 12A. FIG. 12C is a cross-sectional view illustrating the structure taken along line B-B′ illustrated in FIG. 12A.

Referring to FIGS. 12A to 12C, a nano sheet dielectric layer 25 may be formed on exposed portions of the narrow sheets 13P. The nano sheet dielectric layer 25 may be referred to as a “gate dielectric layer”.

The nano sheet dielectric layer 25 may be formed by oxidizing the surfaces of the narrow sheets 13P. In some embodiments, the nano sheet dielectric layer 25 may be formed by a deposition process and an oxidation process of silicon oxide. The nano sheet dielectric layer 25 may include silicon oxide, silicon nitride, metal oxide, metal oxide nitride, metal silicate, a high-k material, a ferroelectric material, an anti-ferroelectric material, or a combination thereof. The nano sheet dielectric layer 25 may include SiO₂, Si₃N₄, HfO₂, Al₂O₃, ZrO₂, AlON, HfON, HfSiO, HfSiON, or a combination thereof. The nano sheet dielectric layer 25 may be formed on all surfaces of the narrow sheets 13P.

The first spacer layer 26A may be formed on the nano sheet dielectric layer 25. The first spacer layer 26A may include silicon nitride. The first spacer layer 26A may surround and cover the narrow sheets 13P on the nano sheet dielectric layer 25. The first spacer layer 26A may be thicker than the nano sheet dielectric layer 25.

A second inter-cell dielectric layer 27A may be formed on the first spacer layer 26A. The second inter-cell dielectric layer 27A may each include silicon oxide.

The nano sheet dielectric layer 25 and the first spacer layer 26A may also be formed on the surface of the substrate 11.

As described above, the first spacer layer 26A may be disposed between the narrow sheets 13P in the third direction D3.

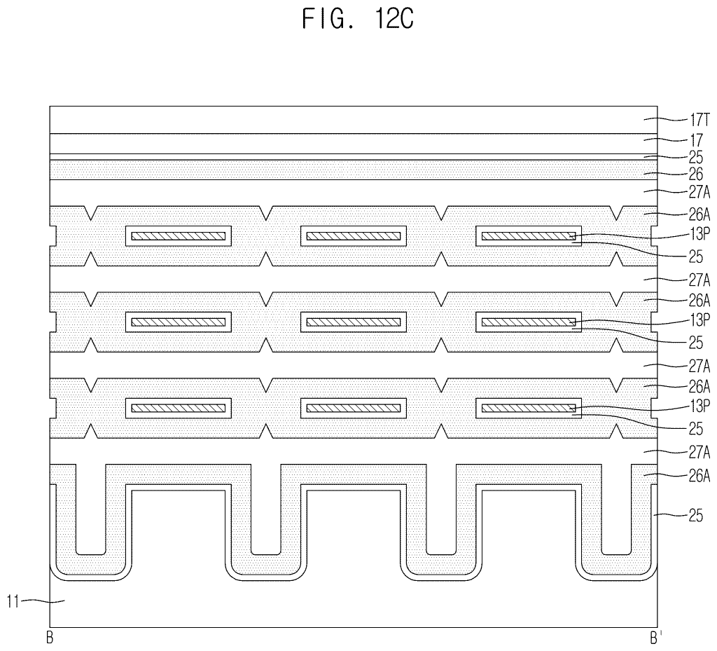

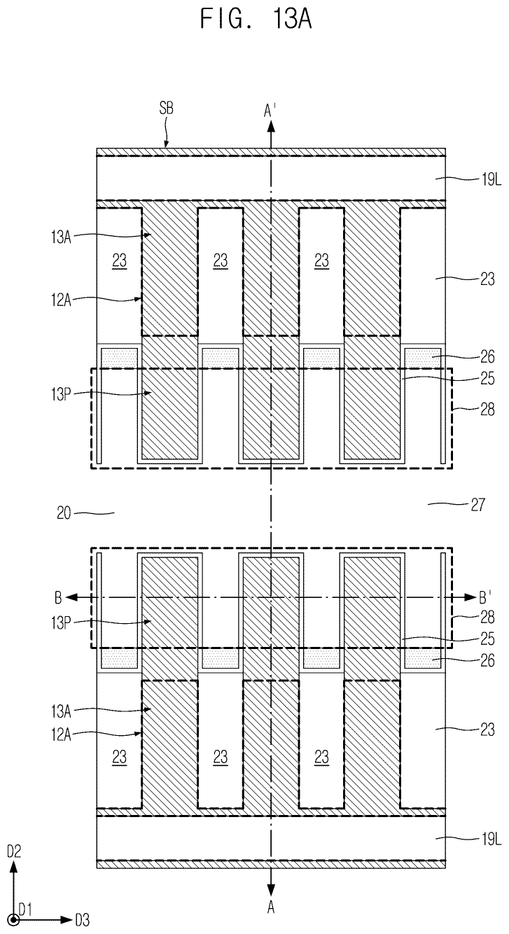

FIG. 13A is a plan view illustrating the structure at the narrow sheet level to describe a method for forming first spacers 26. FIG. 13B is a cross-sectional view illustrating the structure taken along line A-A′ illustrated in FIG. 13A. FIG. 13C is a cross-sectional view illustrating the structure taken along line B-B′ illustrated in FIG. 13A.

Referring to FIGS. 13A to 13C, the second inter-cell dielectric layer 27A may be cut through the first linear opening 20. Subsequently, the first spacer layer 26A may be selectively recessed. The remaining first spacer layer may become the first spacer 26, and the second inter-cell dielectric layer may remain as indicated by reference numeral “27”. The spacer 26 may surround portions of narrow sheets 13P of the same horizontal level spaced along the third direction D3.

As the first spacers 26 are formed, linear surrounding recesses 28 surrounding the narrow sheets 13P may be formed on the nano sheet dielectric layers 25. The second inter-cell dielectric layers 27 may be disposed between the linear surrounding recesses 28 that are vertically disposed. An upper-level dummy horizontal recess 28U may be formed on the second inter-cell dielectric layer 27 at the uppermost level. A lower-level dummy horizontal recess 28L may be formed under the second inter-cell dielectric layer 27 at the lowermost level. The upper-level and lower-level dummy horizontal recesses 28U and 28L may each have a non-surrounding shape, i.e., a flat shape.

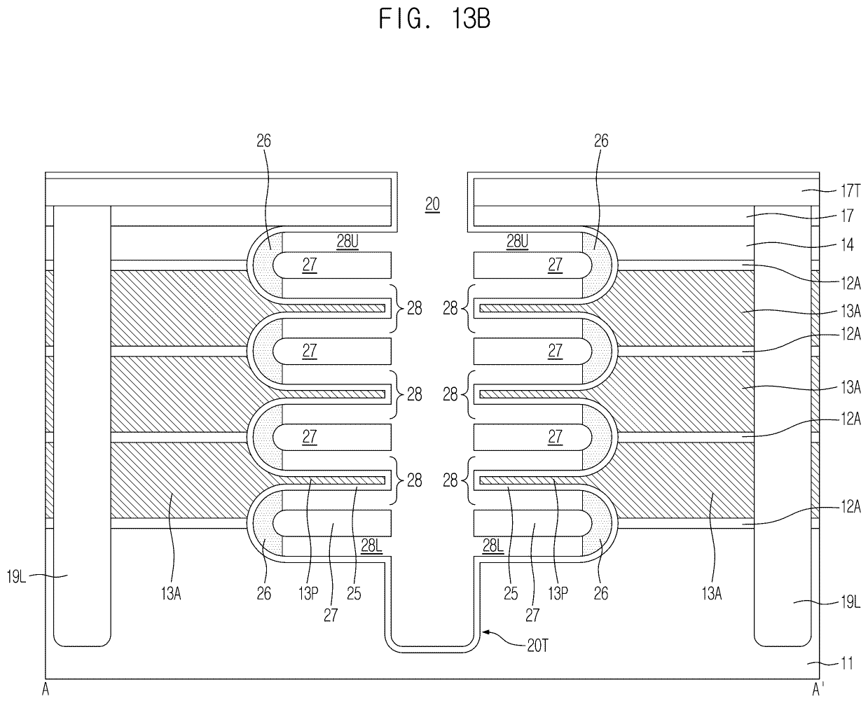

FIG. 14A is a plan view illustrating the structure at the narrow sheet level to describe a method for forming horizontal conductive lines 29. FIG. 14B is a cross-sectional view illustrating the structure taken along line A-A′ illustrated in FIG. 14A. FIG. 14C is a cross-sectional view illustrating the structure taken along line B-B′ illustrated in FIG. 14A.

Referring to FIGS. 14A to 14C, the horizontal conductive lines 29 filling the linear surrounding recesses 28 may be formed. The horizontal conductive lines 29 may horizontally extend in the third direction D3.

Forming the horizontal conductive lines 29 may include depositing a conductive material filling the linear surrounding recesses 28 on the nano sheet dielectric layer 25 and performing a horizontal etch-back process on the conductive material. Each of the horizontal conductive lines 29 may simultaneously surround the narrow sheets 13P at the same level. The horizontal conductive lines 29 may each include a metal-based material, a semiconductor material, or a combination thereof. The horizontal conductive lines 29 may each include molybdenum, molybdenum nitride, ruthenium, titanium nitride, tungsten, polysilicon, or a combination thereof. For example, the horizontal conductive lines 29 may each include a titanium nitride and tungsten (TiN/W) stack in which titanium nitride and tungsten are sequentially stacked. The horizontal conductive lines 29 may each include an N-type work function material or a P-type work function material. The N-type work function material may have a low work function of approximately 4.5 eV or lower. The P-type work function material may have a high work function of approximately 4.5 eV or higher. The second inter-cell dielectric layers 27 may be disposed between a plurality of horizontal conductive lines 29 in the first direction D1. The horizontal conductive lines 29 surrounding the narrow sheets 13P may be referred to as “gate-all-around (GAA) electrodes”. The narrow sheets 13P may be referred to as “nano sheet channels”, “nano wires” or “nano wire channels”.

A lower-level dummy horizontal electrode 29L may be formed on the surface of the substrate 11. An upper-level dummy horizontal electrode 29U may be formed over the uppermost horizontal conductive line 29. The dummy horizontal electrodes 29L and 29U may each have a non-surrounding shape.

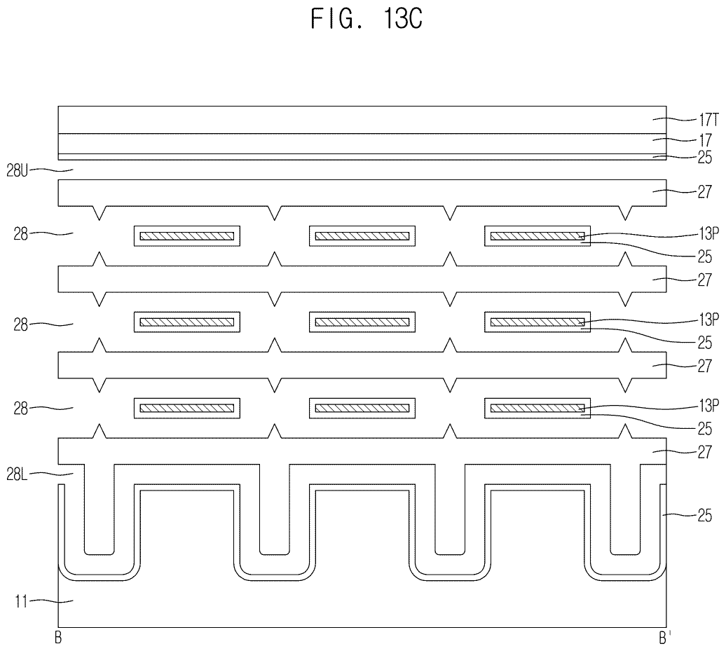

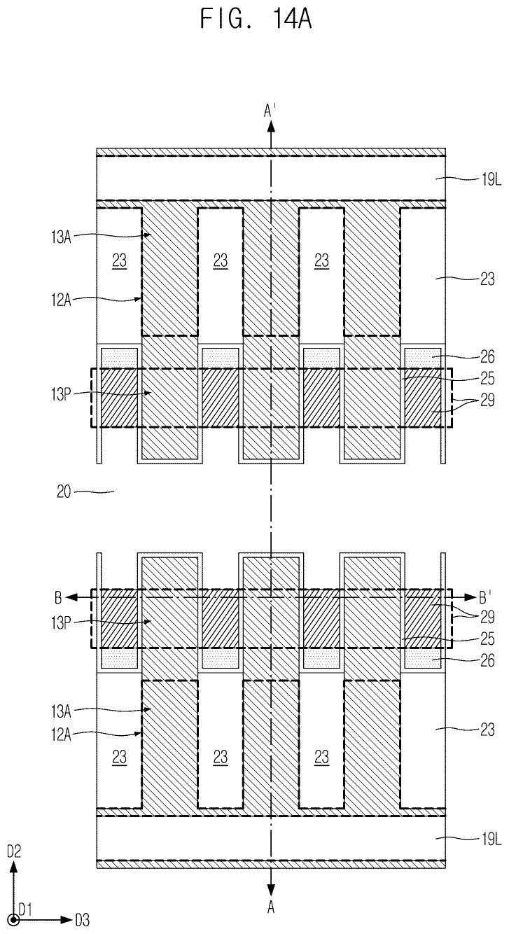

FIG. 15A is a plan view illustrating the structure at the narrow sheet level to describe a method for forming second spacers 30 and 31. FIG. 15B is a cross-sectional view illustrating the structure taken along line A-A′ illustrated in FIG. 15A.

Referring to FIGS. 15A and 15B, the second spacer 30 may be formed on one side of the horizontal conductive line 29. The second spacer 30 may include silicon oxide, silicon nitride, silicon carbon oxide, an embedded air gap, or a combination thereof. Deposition and etch-back processes of a spacer material may be performed to form the second spacer 30. The second spacer 30 may include a stack of a silicon oxide liner 31A and a silicon nitride liner 31B. A portion of the silicon nitride liner 31B may protrude.

After the second spacer 30 is formed, a portion of the nano sheet dielectric layer 25 may be cut to expose each side of the narrow sheets 13P.

Subsequently, the deposition and etch-back processes may be performed on a first bottom passivation layer 32. An upper surface of the first bottom passivation layer 32 may be disposed at a level lower than the horizontal conductive line 29 at the lowermost level. The first bottom passivation layer 32 may include a dielectric material.

The second spacer 30 may be disposed on side of the horizontal conductive lines 29. The second spacer 30 may surround portions of narrow sheets 13P of the same horizontal level spaced along the third direction D3.

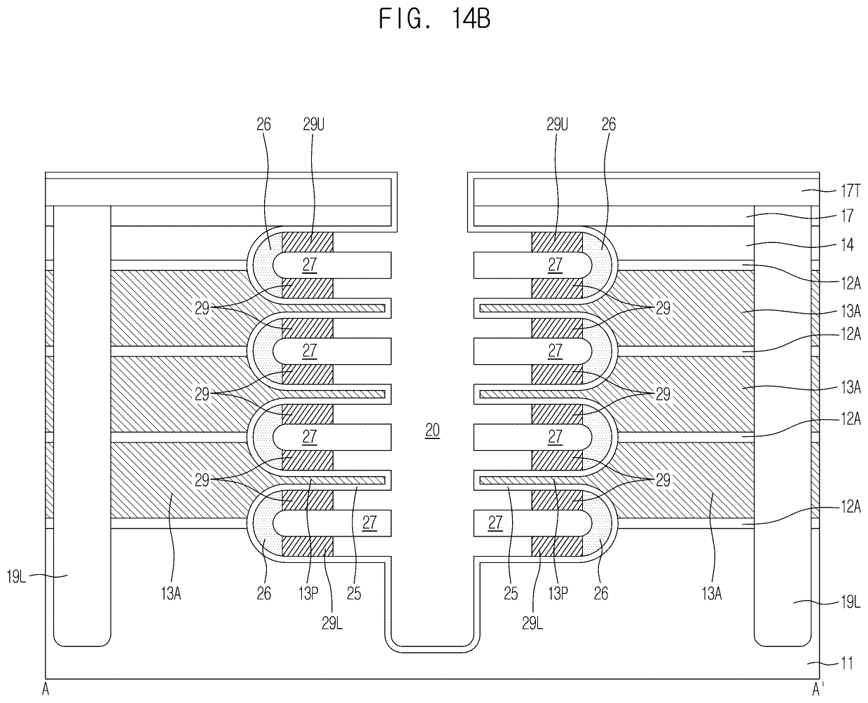

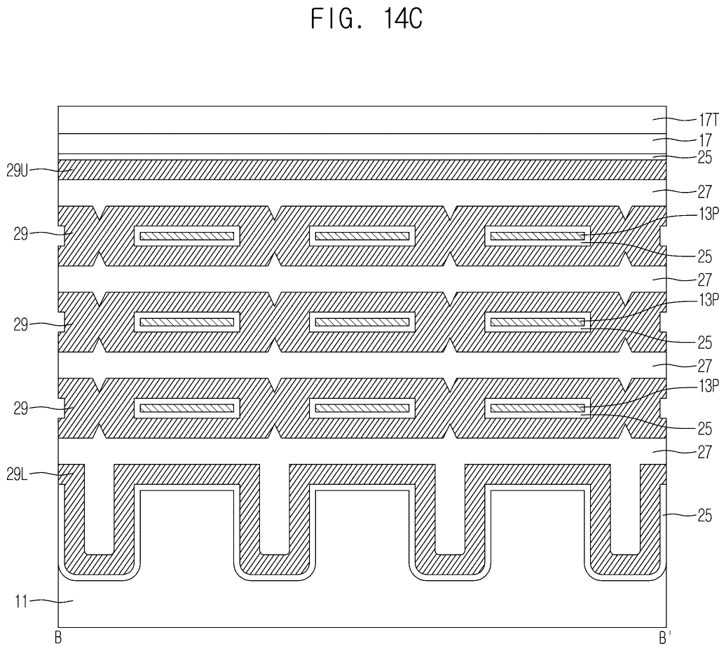

FIG. 16A is a plan view illustrating the structure at the narrow sheet level to describe a method for recessing the narrow sheets 13P. FIG. 16B is a cross-sectional view illustrating the structure taken along line A-A′ illustrated in FIG. 16A.

Referring to FIGS. 16A and 16B, the narrow sheets 13P may be horizontally recessed. Nano sheet level recesses 33 may be formed by the recessing of the narrow sheets 13P. Each of the nano sheet level recesses 33 may be disposed in the second spacer 30. The nano sheet level recess 33 may be an undercut defined in the inner space of the second spacer 30.

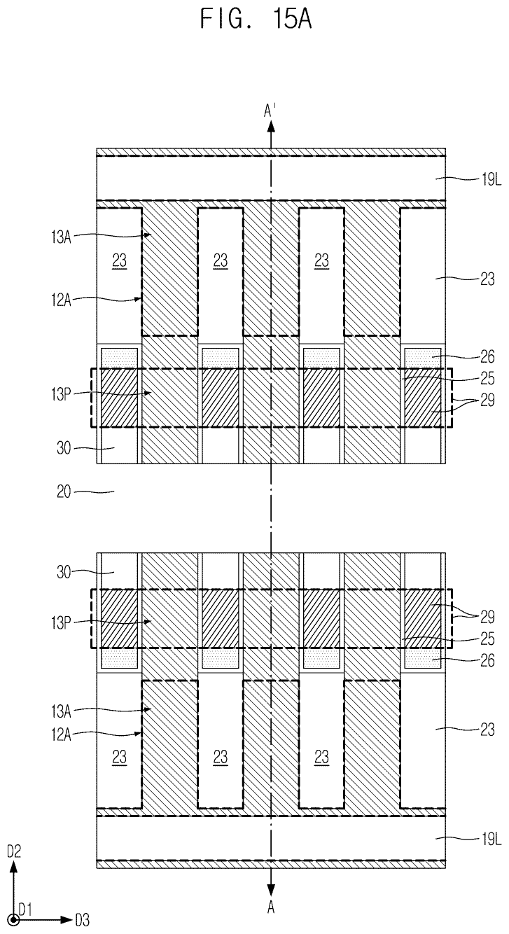

FIG. 17A is a plan view illustrating the structure at the narrow sheet level to describe a method for forming first contact nodes 34. FIG. 17B is a cross-sectional view illustrating the structure taken along line A-A′ illustrated in FIG. 17A.

Referring to FIGS. 17A and 17B, the first contact nodes 34 may be formed to fill the nano sheet level recesses 33. Forming the first contact nodes 34 may include depositing a conductive material filling the nano sheet level recesses 33 and performing an etch-back process on the conductive material. The first contact nodes 34 may each include a semiconductor material. The first contact nodes 34 may each include doped polysilicon, and the doped polysilicon may include N-type dopants. Each of the first contact nodes 34 may be disposed between the second spacers 30 that are vertically stacked. The first contact nodes 34 and the second spacers 30 may not be self-aligned in the first direction D1. That is, the first contact nodes 34 may partially fill the undercut between the second spacers 30 that are vertically stacked.

First doped regions 35 may be formed within sides of the narrow sheets 13P. A heat treatment process may be performed to form the first doped regions 35, and thus the dopants may be diffused from the first contact nodes 34. In another method for forming the first doped regions 35, a selective epitaxial growth (SEG) or gas phase doping method may be applied.

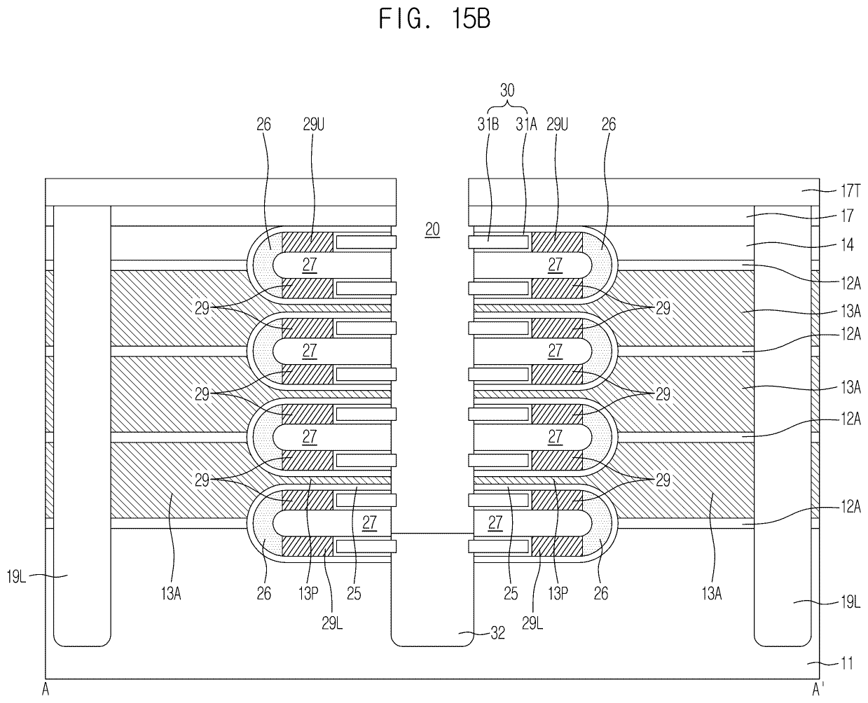

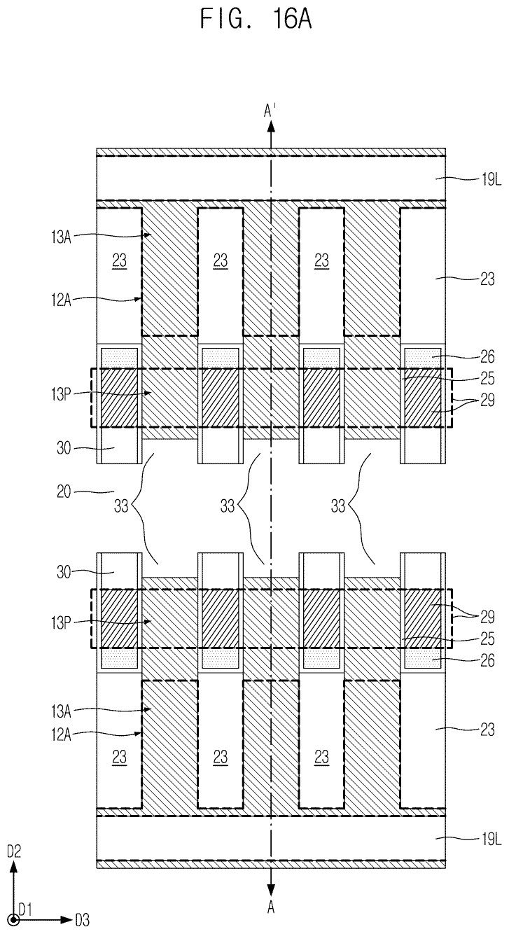

FIG. 18A is a plan view illustrating the structure at the narrow sheet level to describe a method for forming vertical conductive lines 37A and 37B. FIG. 18B is a cross-sectional view illustrating the structure taken along line A-A′ illustrated in FIG. 18A.

Referring to FIGS. 18A and 18B, ohmic contact layers 36 may be formed on the first contact nodes 34. The ohmic contact layers 36 may each include metal silicide.

The vertical conductive lines 37A and 37B may be formed on the ohmic contact layers 36. The vertical conductive lines 37A and 37B may be coupled in common to the ohmic contact layers 36. Accordingly, the vertical conductive lines 37A and 37B may be coupled in common to the narrow sheets 13P disposed in the first direction D1. The vertical conductive lines 37A and 37B may each include a metal-based material. The vertical conductive lines 37A and 37B may each include titanium nitride, tungsten, or a combination thereof.

The deposition and etch processes may be performed on a vertical conductive line material to form the vertical conductive lines 37A and 37B.

Bottom portions 38 of the vertical conductive lines 37A and 37B may be merged with each other. The vertical conductive lines 37A and 37B may be disposed in the first linear opening 20. The vertical conductive lines 37A and 37B may vertically extend in the first direction D1. The bottom portions 38 of the vertical conductive lines 37A and 37B may be merged with each other. The vertical conductive lines 37A and 37B may be coupled in common to the ohmic contact layers 36. Accordingly, the vertical conductive lines 37A and 37B may be coupled in common to the narrow sheets 13P disposed in the first direction D1.

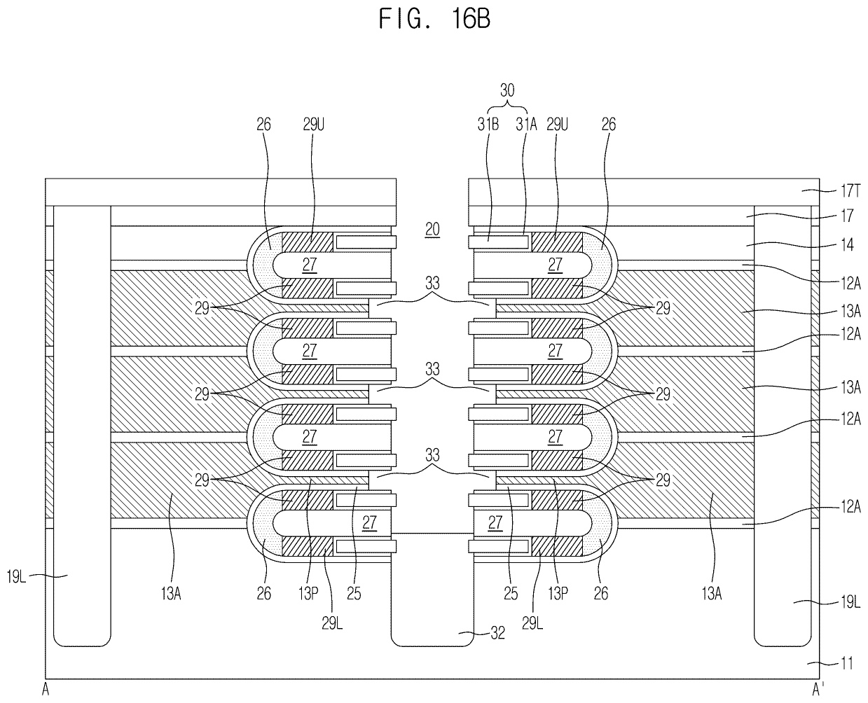

FIG. 19A is a plan view illustrating the structure at a nano sheet level to describe a method for forming second linear openings 41. FIG. 19B is a cross-sectional view illustrating the structure taken along line A-A′ illustrated in FIG. 19A.

Referring to FIGS. 19A and 19B, a vertical isolation layer 39 may be formed to fill the first linear opening 20 on the vertical conductive lines 37A and 37B. The vertical isolation layer 39 may vertically extend in the first direction D1 and horizontally extend in the third direction D3. The vertical conductive lines 37A and 37B disposed adjacent to each other in the third direction D3 may be isolated by the vertical isolation layer 39. The vertical isolation layer 39 may include a dielectric material. The vertical isolation layer 39 may include silicon oxide, silicon nitride, an air gap, or a combination thereof.

Subsequently, the second linear sacrificial layer 19L may be removed using the fourth hard mask layer 40 as a barrier. Accordingly, the second linear openings 41 may be formed.

After the second linear openings 41 is formed, the first mold layers 12A may be selectively recessed through the second linear openings 41. In order to selectively recess the first mold layers 12A, the difference in etch selectivity between the first mold layers 12A and the original body portions 13A may be used. The first mold layers 12A may be removed using a wet etch process or a dry etch process. For example, when the first mold layers 12A include silicon germanium layers and the original body portions 13A include monocrystalline silicon layers, the silicon germanium layers may be etched using an etchant or etching gas having a selectivity with respect to the monocrystalline silicon layers.

Subsequently, the original body portions 13A may be recessed. To recess the original body portions 13A, the wet etch process or the dry etch process may be used. Vertical thicknesses of the original body portions 13A may be reduced, as indicated by reference numeral “13S”. Hereinafter, the original body portions having the reduced vertical thicknesses are referred to as “recessed body portions 13S”.

An inter-body recess 42 may be formed between the recessed body portions 13S that are vertically disposed.

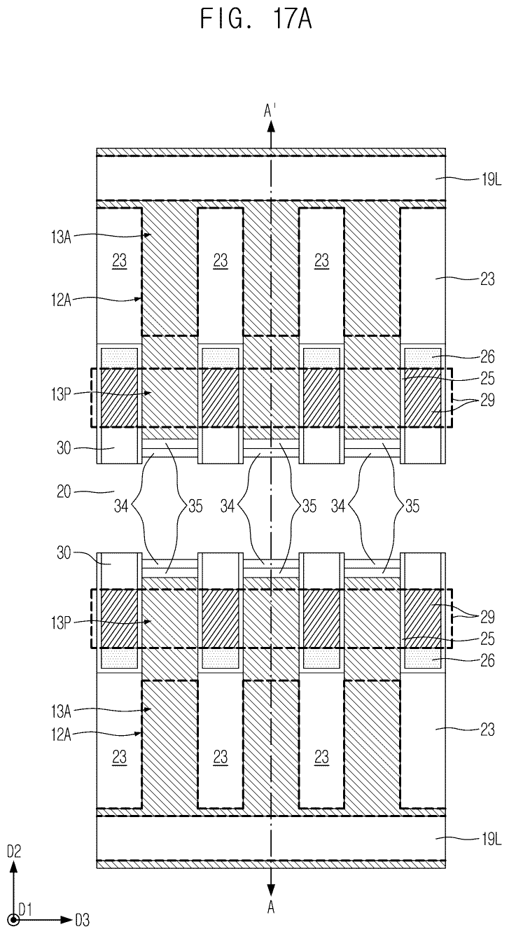

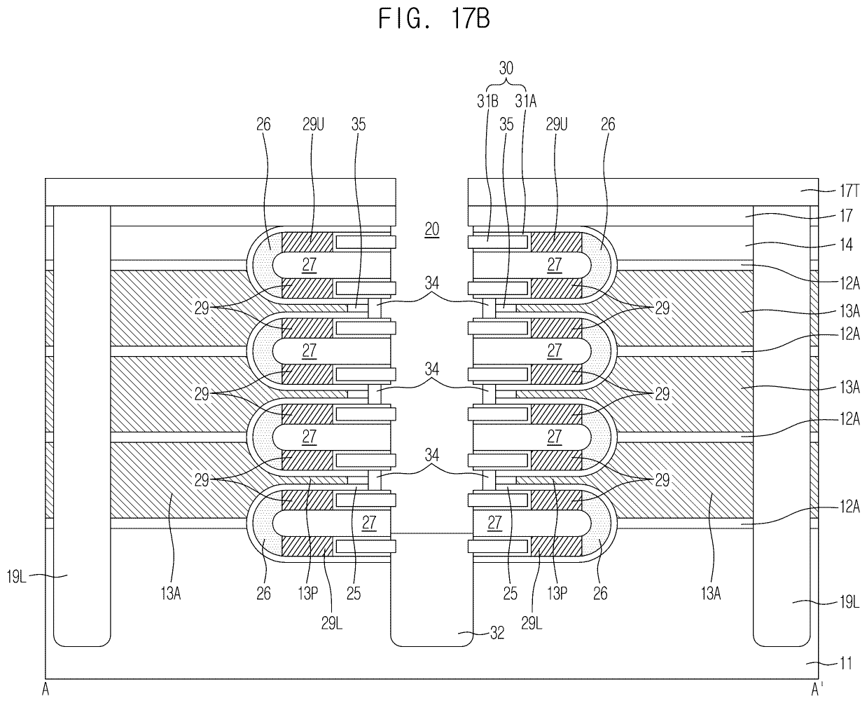

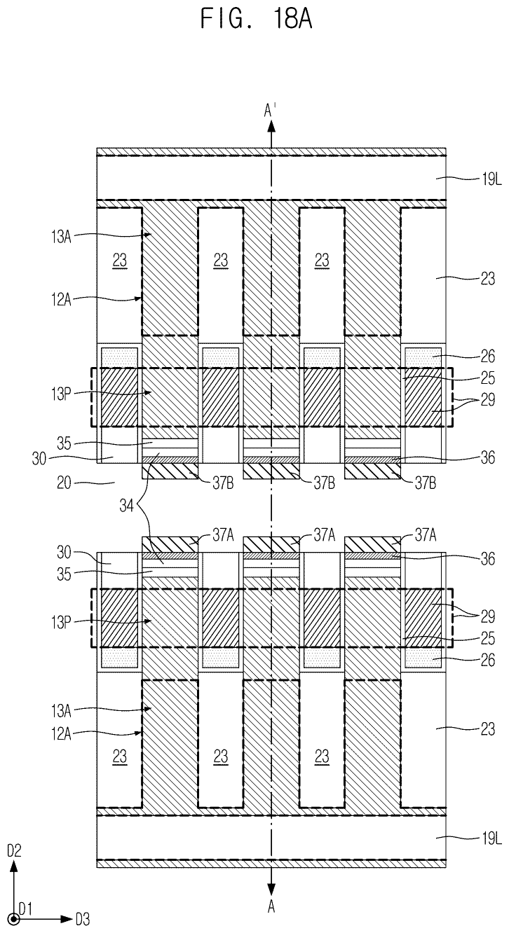

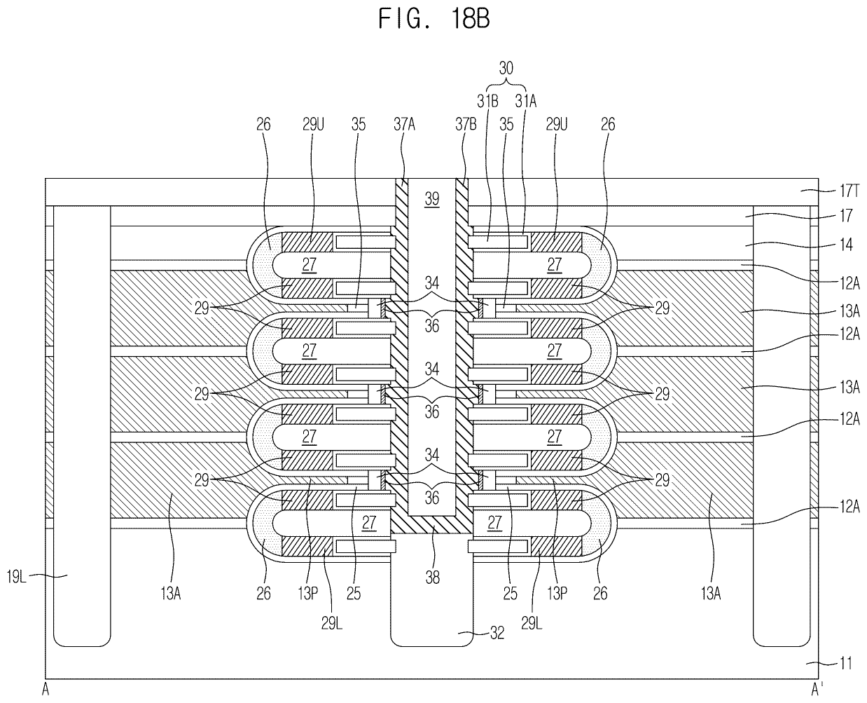

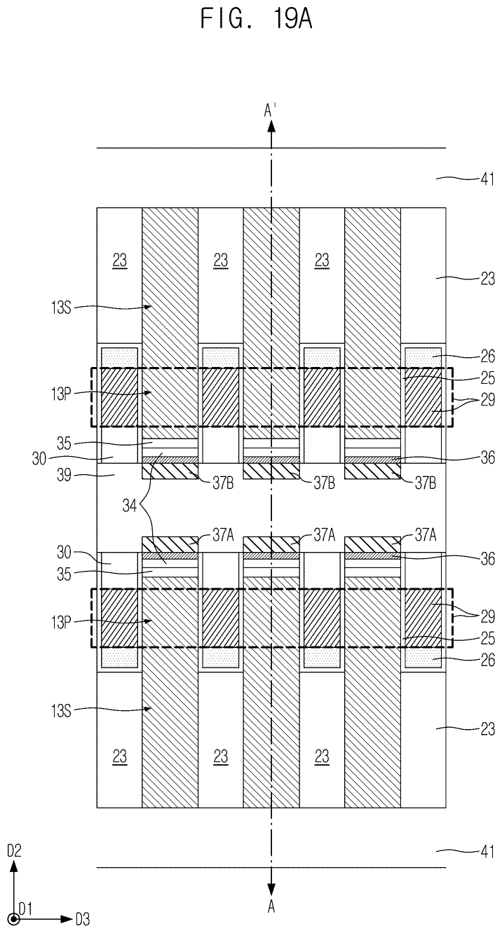

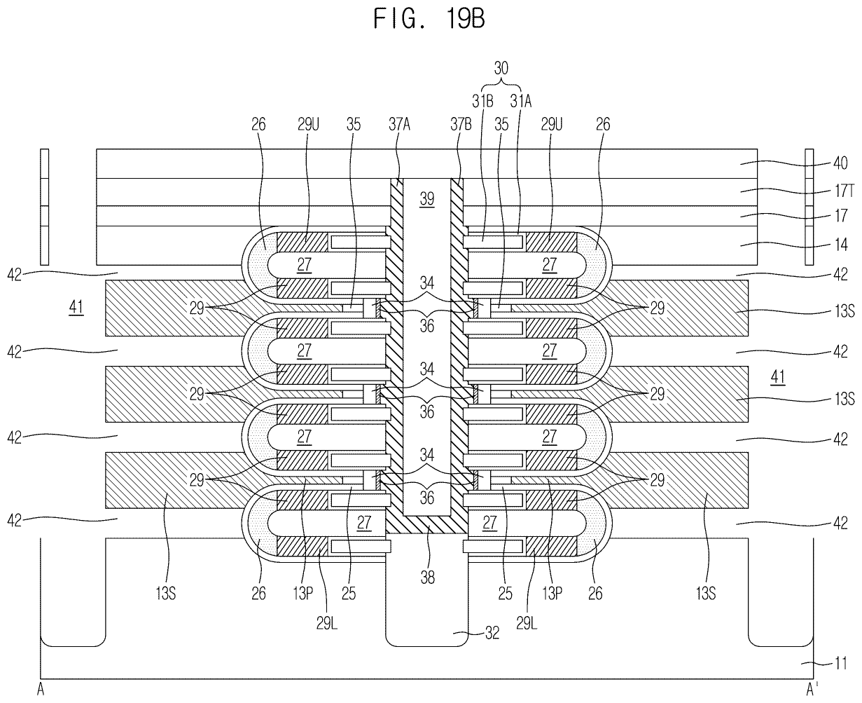

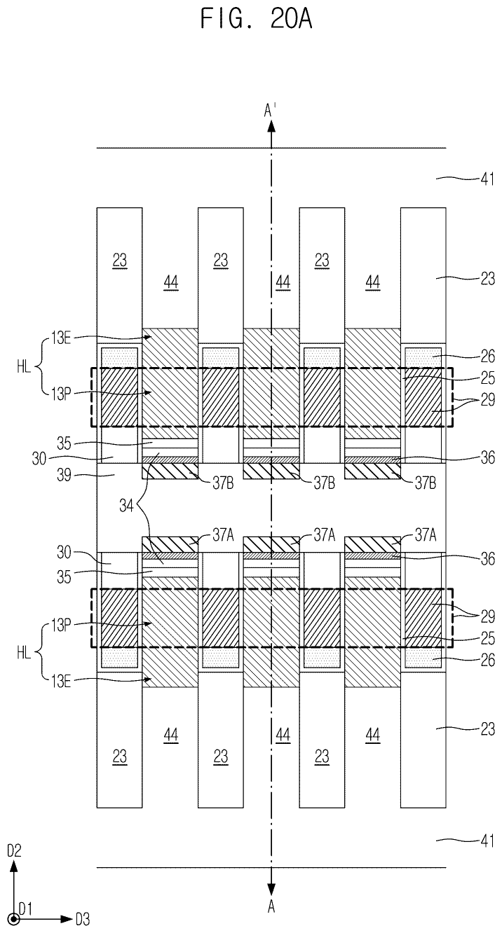

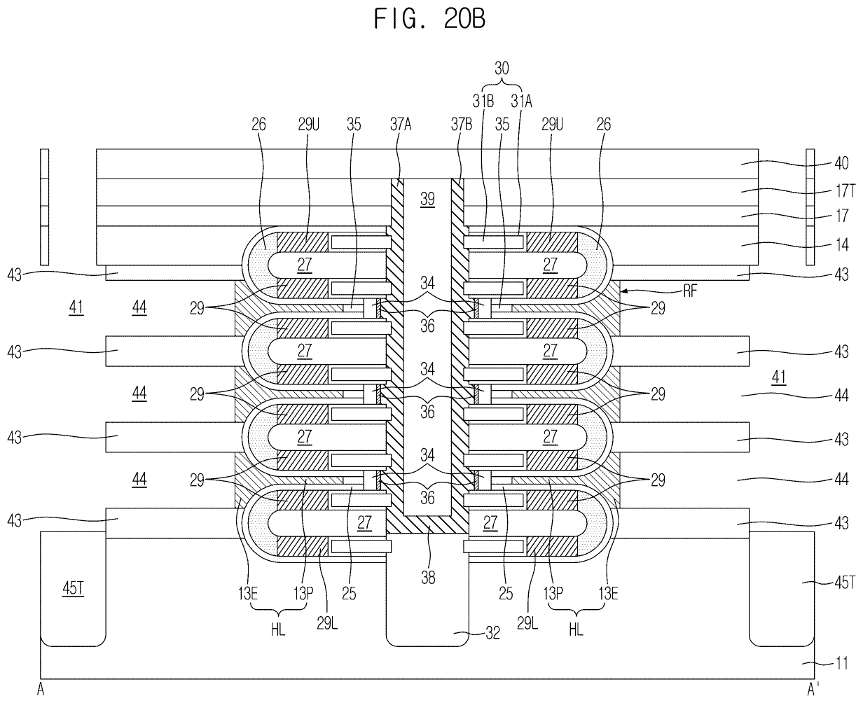

FIG. 20A is a plan view illustrating the structure at the narrow sheet level to describe a method for forming nano sheets HL. FIG. 20B is a cross-sectional view illustrating the structure taken along line A-A′ illustrated in FIG. 20A.

Referring to FIGS. 20A and 20B, third inter-cell dielectric layers 43 may be formed to fill the inter-body recesses 42. The third inter-cell dielectric layers 43 may each include silicon oxide.

After the third inter-cell dielectric layers 43 are formed, second bottom passivation layers 45T may be formed to fill bottom portions of the second linear openings 41. The second bottom passivation layers 45T may each include a dielectric material. The second bottom passivation layers 45T may include silicon oxide, silicon nitride, silicon carbon oxide, or a combination thereof.

After the second bottom passivation layers 45T are formed, storage openings 44 may be formed by horizontal recessing of the recessed body portions 13S. The storage openings 44 may be referred to as “capacitor openings”. The nano sheets HL may be formed by the horizontal recessing of the recessed body portions 13S. Each of the nano sheets HL may include a narrow sheet 13P and a wide sheet 13E. The wide sheet 13E of the nano sheet HL may refer to the recessed body portion 13S remaining after the recessing. An average vertical height of the wide sheet 13E of the nano sheet HL in the first direction D1 may be greater than an average vertical height of the narrow sheet 13P. A thickness of the wide sheet 13E of the nano sheet HL may gradually increase in the second direction D2. A horizontal length of the wide sheet 13E in the second direction D2 may be less than a horizontal length of the narrow sheet 13P. The wide sheet 13E of the nano sheet HL may have a fan-like shape. The wide sheet 13E may be referred to as a “fan-shaped sheet”, and the narrow sheet 13P may be referred to as a “flat plate-shaped sheet”.

To form the nano sheets HL each including the wide sheet 13E, the recessed body portions 13S may be isotropically or anisotropically etched. One side of the wide sheet 13E, i.e., the side exposed by each of the storage openings 44, may have a flat shape (refer to reference symbol “RF”). The one side of the wide sheet 13E may have various shapes, which are to be described later.

Each of the nano sheets HL may include a first edge and a second edge. The first edge may refer to a portion electrically coupled to the vertical conductive lines 37A and 37B, the first contact node 34, and the ohmic contact layer 36. The second edge may refer to a portion exposed by each of the storage openings 44.

Each of the storage openings 44 may be disposed between the third inter-cell dielectric layers 43.

In some embodiments, the horizontal recessing of the recessed body portions 13S for forming the wide sheets 13E may stop at a boundary area between the narrow sheet 13P and the wide sheet 13E. The second bottom passivation layers 45T may prevent loss of the substrate 11 during the recessing process of the recessed body portions 13S.

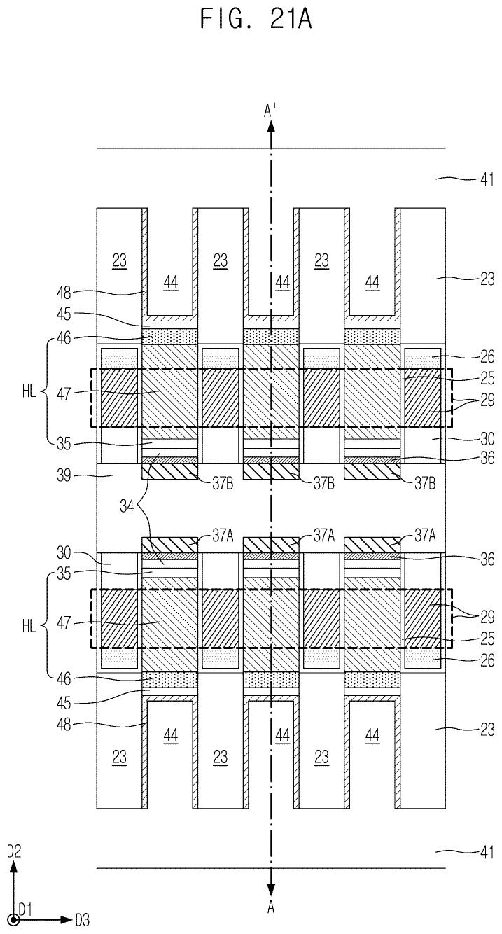

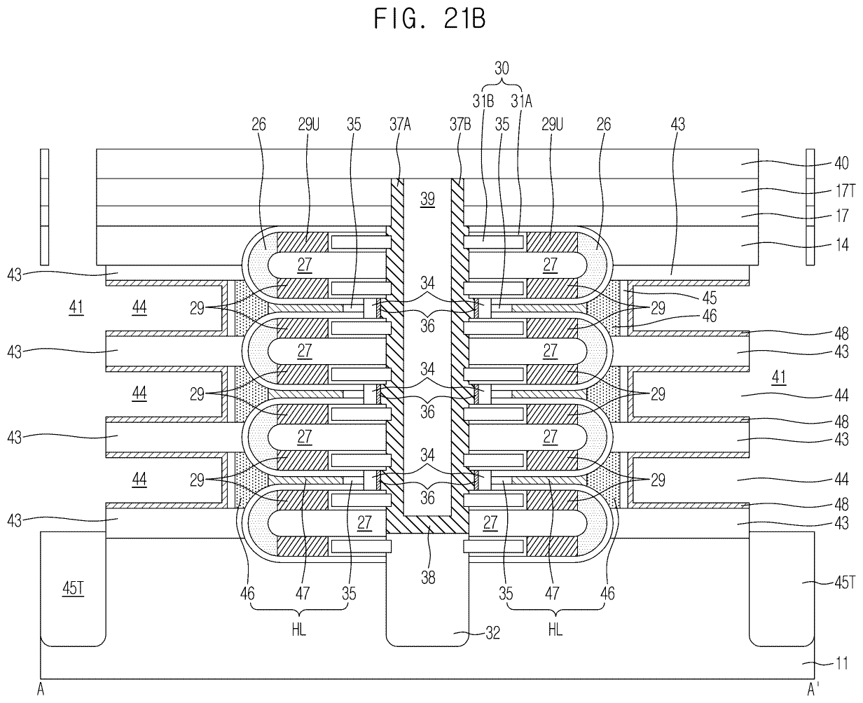

FIG. 21A is a plan view illustrating the structure at the nano sheet level to describe a method for forming second contact nodes 45 and first electrodes 48. FIG. 21B is a cross-sectional view illustrating the structure taken along line A-A′ illustrated in FIG. 21A.

Referring to FIGS. 21A and 21B, a pre-cleaning process may be performed on one side of the nano sheets HL, that is, the surfaces of the wide sheets 13E.

Subsequently, the second contact nodes 45 may be formed on one side of the nano sheets HL, that is, the wide sheets 13E. Forming the second contact nodes 45 may include selective epitaxial growth (SEG). For example, a semiconductor material may be grown from the side surfaces of the wide sheets 13E through the selective epitaxial growth (SEG). The second contact nodes 45 may each include SEG Si. Since the wide sheets 13E each include monocrystalline silicon, a silicon layer may be epitaxially grown along crystal surfaces of the side surfaces of the wide sheets 13E.

The second contact nodes 45 may each include a dopant. When the silicon layer is grown using selective epitaxial growth (SEG), dopants may be doped in situ. Accordingly, the second contact nodes 45 may each be a doped epitaxial layer. The second contact nodes 45 may each include an N-type dopant as the dopant. The N-type dopant may include phosphorus, arsenic, antimony, or a combination thereof. The second contact nodes 45 may include a phosphorus-doped silicon epitaxial layer formed by the selective epitaxial growth (SEG), i.e., a doped SEG SiP. In some embodiments, the first contact nodes 34 may also be formed by the selective epitaxial growth (SEG).

Since the second contact nodes 45 are formed using the selective epitaxial growth (SEG), void-free or seam-free second contact nodes 45 may be formed. Since the second contact nodes 45 are formed using the selective epitaxial growth (SEG), a process for forming the second contact nodes 45 may be simplified.

Each of the second contact nodes 45 may be disposed between the third inter-cell dielectric layers 43 that are vertically stacked.

Second doped regions 46 may be formed in the wide sheets 13E of the nano sheets HL. A heat treatment process may be performed to form the second doped regions 46, and thus, dopants may be diffused from the second contact nodes 45.

Each of the nano sheets HL may include the first doped region 34, the second doped region 46, and a channel 47. The channel 47 may be defined between the first doped region 34 and the second doped region 46. The first doped region 34 and the channel 47 may be formed in the narrow sheet 13P. The second doped region 46 may be formed in the wide sheet 13E. A portion of each of the second doped regions 46 may extend into the narrow sheets 13P. One side of each of the second doped regions 46 of the nano sheets HL may be coupled to the channel 47. The other side of each of the second doped regions 46 of the nano sheets HL may be coupled to the second contact nodes 45.

In some embodiments, an ohmic contact layer including metal silicide may be further formed after the second contact nodes 45 are formed.

Subsequently, the first electrodes 48 of a data storage element may be formed on the second contact nodes 45. The first electrodes 48 may each have a horizontally oriented cylindrical shape. The first electrodes 48 may be respectively disposed in the storage openings 44. The first electrodes 48 disposed adjacent to each other in the second direction D2 may be spaced apart from each other by the second linear openings 41. The first electrodes 48 disposed adjacent to each other in the third direction D3 may be spaced apart from each other by the first inter-cell dielectric layers 23. The first electrodes 48 disposed adjacent to each other in the first direction D1 may be spaced apart from each other by the third inter-cell dielectric layers 43. Forming the first electrodes 48 may include depositing a metal material, gap-filling a sacrificial material, and isolating the metal material in a vertical/horizontal direction. The sacrificial material may include oxide or polysilicon.

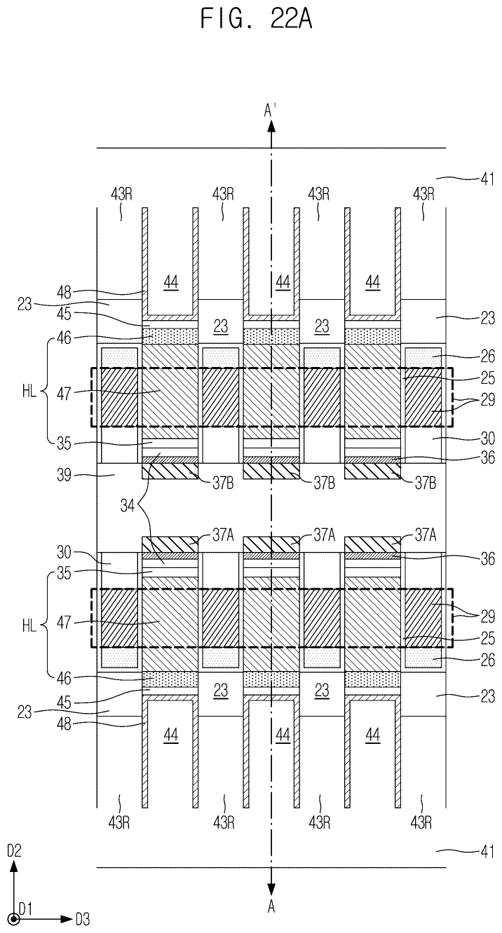

FIG. 22A is a plan view illustrating the structure at the nano sheet level to describe a method for recessing first and third inter-cell dielectric layers 23 and 43. FIG. 22B is a cross-sectional view illustrating the structure taken along line A-A′ illustrated in FIG. 22A.

Referring to FIGS. 22A and 22B, portions of the first and third inter-cell dielectric layers 23 and 43 may be horizontally recessed (refer to reference numeral “43R”). Accordingly, the outer walls of the first electrodes 48 may be partially exposed. The first electrodes 48 may each have a semi-cylindrical shape. Horizontal recess depths of the first and third inter-cell dielectric layers 23 and 43 may be a depth that does not expose the second contact nodes 45.

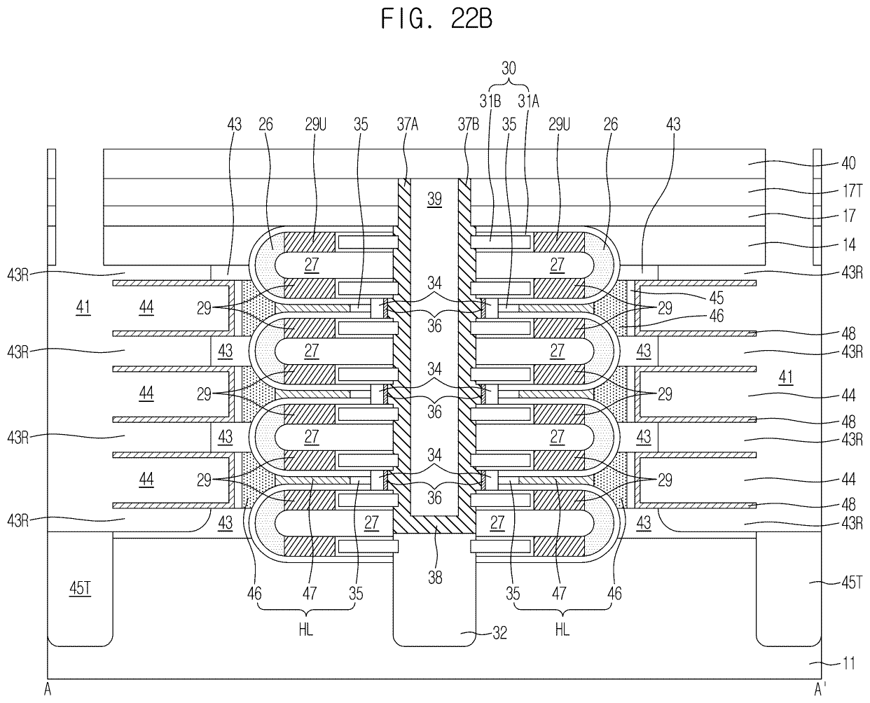

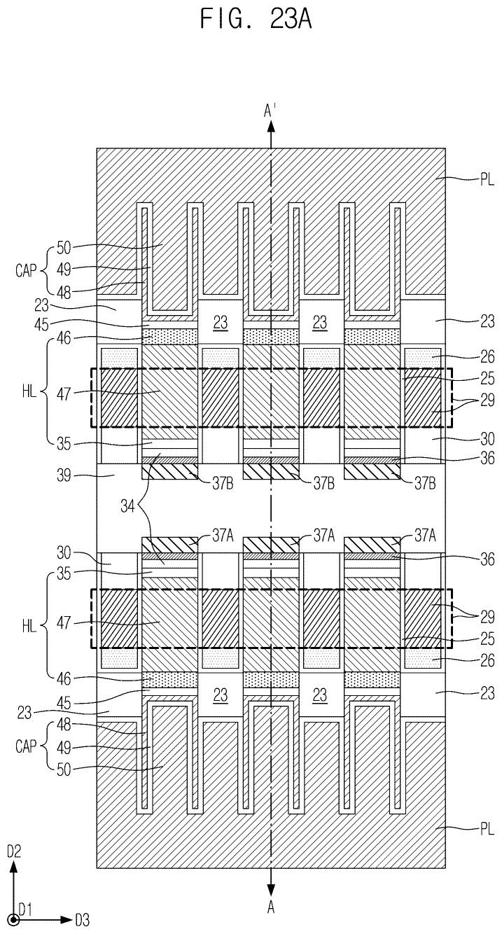

FIG. 23A is a plan view illustrating the structure at the nano sheet level to describe a method for forming a second electrode 50 of the data storage element. FIG. 23B is a cross-sectional view illustrating the structure taken along line A-A′ illustrated in FIG. 23A.

Referring to FIGS. 23A and 23B, a dielectric layer 49 and the second electrode 50 may be sequentially formed on the first electrodes 48. The first electrode 48, the dielectric layer 49, and the second electrode 50 may be the data storage element CAP.

The first electrode 48 may include an inner space and a plurality of outer surfaces. The inner space of the first electrode 48 may include a plurality of inner surfaces. The outer surfaces of the first electrode 48 may include a vertical outer surface and a plurality of horizontal outer surfaces. The vertical outer surface of the first electrode 48 may vertically extend in the first direction D1. The horizontal outer surfaces of the first electrode 48 may horizontally extend in the second direction D2 or the third direction D3. The inner space of the first electrode 48 may be a three-dimensional space. The dielectric layer 49 may conformally cover the inner surfaces and horizontal outer surfaces of the first electrode 48. The second electrode 50 may be disposed on the inner space and horizontal outer surfaces of the first electrode 48 on the dielectric layer 49. Among the outer surfaces of the first electrode 48, the vertical outer surface may be electrically coupled to the nano sheet HL and the second contact node 45.

The first electrode 48 may have a semi-cylindrical shape. The semi-cylindrical shape of the first electrode 48 may include cylindrical inner surfaces and semi-cylindrical outer surfaces. The dielectric layer 49 and the second electrode 50 may be disposed on the cylindrical inner surfaces of the first electrode 48. A portion of the dielectric layer 49 and a portion of the second electrode 50 may extend to be disposed on the semi-cylindrical outer surfaces of the first electrode 48. The second electrode 50 may vertically extend in the first direction D1.

The first electrode 48 and the second electrode 50 may each include metal, noble metal, metal nitride, conductive metal oxide, conductive noble metal oxide, metal carbide, metal silicide, or a combination thereof. For example, the first electrode 48 and the second electrode 50 may each include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof. The second electrode 50 may also include a combination of a metal-based material and a silicon-based material. For example, the second electrode 50 may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material filling the inner space of the first electrode 48, titanium nitride (TiN) may serve as the second electrode 50 of the data storage element CAP, and tungsten nitride may be a low-resistivity material.

The dielectric layer 49 may be referred to as a “capacitor dielectric layer” or a “memory layer”. The dielectric layer 49 may include silicon oxide, silicon nitride, a high-k material, a ferroelectric material, an antiferroelectric material, a perovskite material, or a combination thereof. The dielectric layer 49 may include a high-k material such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 49 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack.

In some embodiments, an interface control layer may be further formed between the first electrode 48 and the dielectric layer 49 to improve leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 50 and the dielectric layer 49.

As described above, a method for fabricating the semiconductor device may include forming the nano sheet target layers 13 that are vertically stacked spaced apart from each other over the substrate 11, forming the flat plate-shaped narrow sheets 13P by trimming first portions of the nano sheet target layers 13, horizontally recessing second portions of the nano sheet target layers 13 to form the fan-shaped wide sheets 13E, selectively growing the second contact nodes 45 on side surfaces of the wide sheets 13E, and forming the data storage element CAP coupled to each of the second contact nodes 45.

From another perspective, a method for fabricating the semiconductor device may include forming the nano sheet target layers 13 that are vertically stacked spaced apart from each other over the substrate 11, forming the flat plate-shaped narrow sheets 13P that trim first portions of the nano sheet target layers 13, forming the horizontal conductive lines 29 extending while surrounding the narrow sheets 13P disposed at the same horizontal level, forming the first contact nodes 34 coupled to the narrow sheets 13P, forming the vertical conductive lines 37A and 37B coupled to the first contact nodes 34, horizontally recessing second portions of the nano sheet target layers 13P to form the fan-shaped wide sheets 13E, selectively growing the second contact nodes 45 on the side surfaces of the wide sheets 13E, and forming the data storage element CAP coupled to each of the second contact nodes 45.

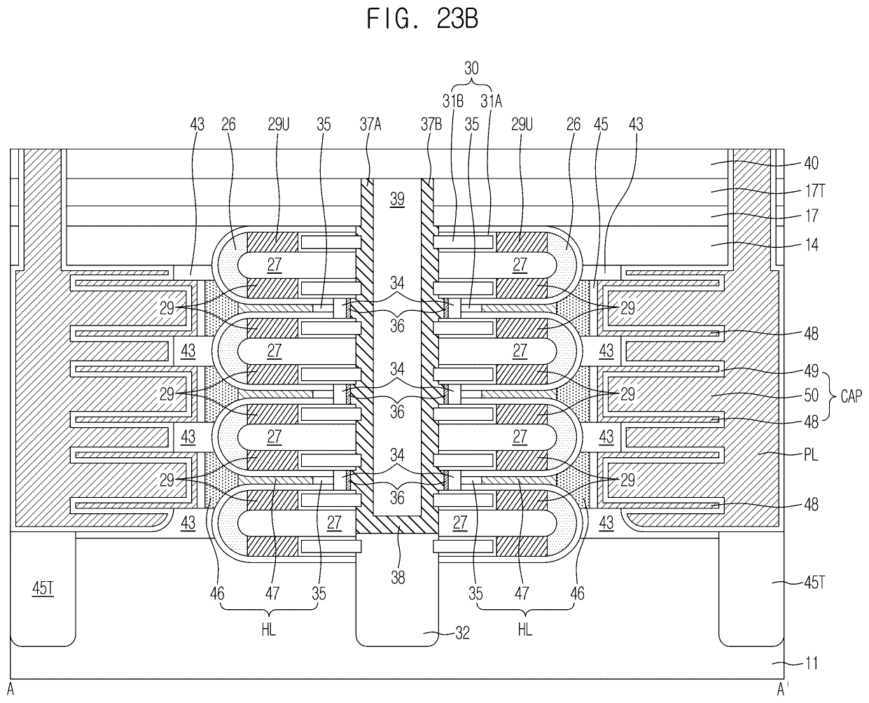

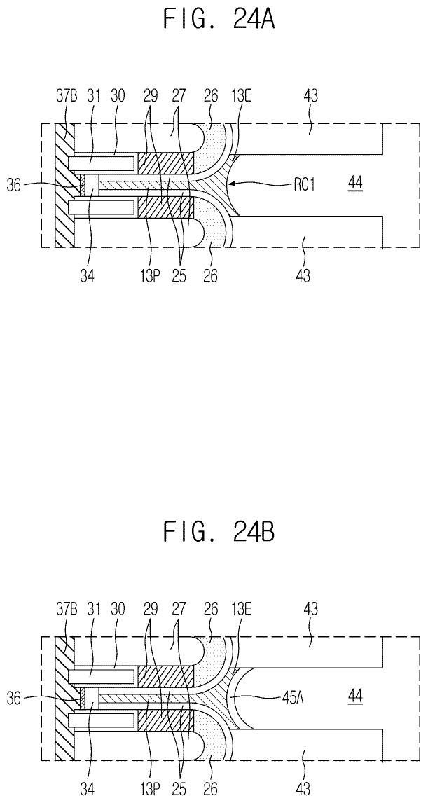

FIGS. 24A to 28B illustrate various views of a semiconductor device formed utilizing a method for fabricating the semiconductor device in accordance with an embodiment of the present disclosure. FIGS. 24A to 28B illustrate other embodiments of a method for forming wide sheets and second contact nodes described above with reference to FIGS. 20A to 21B.

Referring to FIG. 24A, subsequently to FIGS. 19A and 19B, storage openings 44 and wide sheets 13E may be formed by the horizontal recessing of the recessed body portions 13S. The side surfaces of the wide sheets 13E exposed by the storage openings 44 may each have a rounded concave shape RC1.

Referring to FIG. 24B, a second contact node 45A may be formed along the profile of the rounded concave shape RC1 of each of the wide sheets 13E. Forming the second contact node 45A may include selective epitaxial growth (SEG). For example, a semiconductor material may be grown from the side surface of the wide sheet 13E through the selective epitaxial growth (SEG). The second contact node 45A may include SEG Si. The second contact node 45A may include a dopant. Accordingly, the second contact node 45A may be a doped epitaxial layer. The second contact node 45A may include an N-type dopant as the dopant. The N-type dopant may include phosphorus, arsenic, antimony, or a combination thereof. The second contact node 45A may include a phosphorus-doped silicon epitaxial layer, i.e., a doped SEG SiP, formed by selective epitaxial growth (SEG).

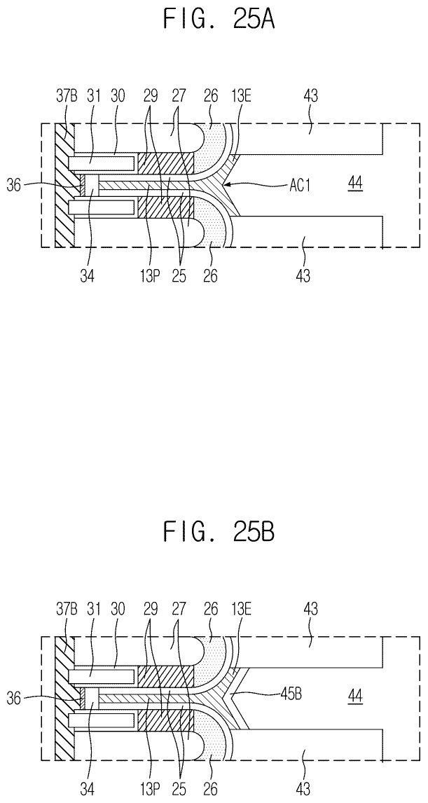

Referring to FIG. 25A, subsequently to FIGS. 19A and 19B, storage openings 44 and wide sheets 13E may be formed by the horizontal recessing of the recessed body portions 13S. The side surfaces of the wide sheets 13E exposed by the storage openings 44 may each have an angled concave shape AC1.

Referring to FIG. 25B, a second contact node 45B may be formed along the profile of the angled concave shape AC1 of each of the wide sheets 13E. Forming the second contact node 45B may include selective epitaxial growth (SEG). For example, a semiconductor material may be grown from the side surface of the wide sheet 13E through the selective epitaxial growth (SEG). The second contact node 45B may include SEG Si. The second contact node 45B may include a dopant. Accordingly, the second contact node 45B may be a doped epitaxial layer. The second contact node 45B may include an N-type dopant as the dopant. The N-type dopant may include phosphorus, arsenic, antimony, or a combination thereof. The second contact node 45B may include a phosphorus-doped silicon epitaxial layer, i.e., a doped SEG SiP, formed by selective epitaxial growth (SEG).

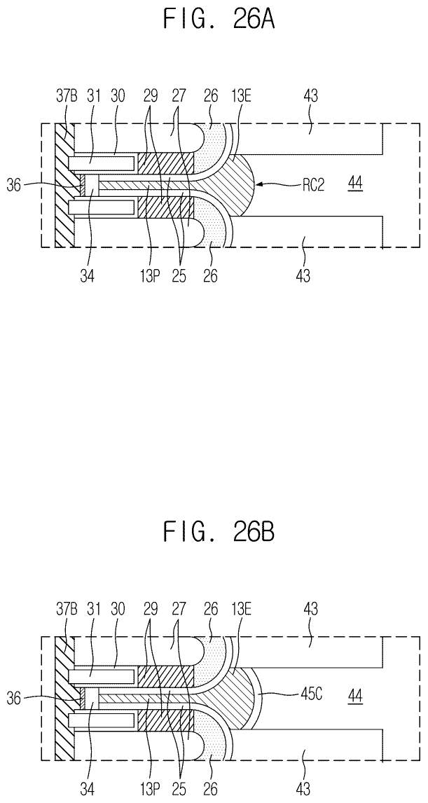

Referring to FIG. 26A, subsequently to FIGS. 19A and 19B, storage openings 44 and wide sheets 13E may be formed by the horizontal recessing of the recessed body portions 13S. The side surfaces of the wide sheets 13E exposed by the storage openings 44 may each have a rounded convex shape RC2.

Referring to FIG. 26B, a second contact node 45C may be formed along the profile of the rounded convex shape RC2 of each of the wide sheets 13E. Forming the second contact node 45C may include selective epitaxial growth (SEG). For example, a semiconductor material may be grown from the side surface of the wide sheet 13E through the selective epitaxial growth (SEG). The second contact node 45C may include SEG Si. The second contact node 45C may include a dopant. Accordingly, the second contact node 45C may be a doped epitaxial layer. The second contact node 45C may include an N-type dopant as the dopant. The N-type dopant may include phosphorus, arsenic, antimony, or a combination thereof. The second contact node 45C may include a phosphorus-doped silicon epitaxial layer, i.e., a doped SEG SiP, formed by selective epitaxial growth (SEG).

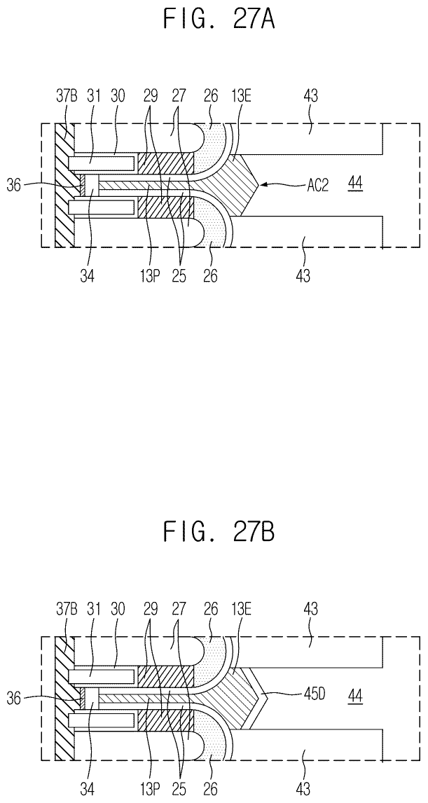

Referring to FIG. 27A, subsequently to FIGS. 19A and 19B, storage openings 44 and wide sheets 13E may be formed by the horizontal recessing of the recessed body portions 13S. The side surfaces of the wide sheets 13E exposed by the storage openings 44 may each have an angled convex shape AC2.

Referring to FIG. 27B, a second contact node 45D may be formed along the profile of the angled convex shape AC2 of each of the wide sheets 13E. Forming the second contact node 45D may include selective epitaxial growth (SEG). For example, a semiconductor material may be grown from the side surface of the wide sheet 13E through the selective epitaxial growth (SEG). The second contact node 45D may include SEG Si. The second contact node 45D may include a dopant. Accordingly, the second contact node 45D may be a doped epitaxial layer. The second contact node 45D may include an N-type dopant as the dopant. The N-type dopant may include phosphorus, arsenic, antimony, or a combination thereof. The second contact node 45D may include a phosphorus-doped silicon epitaxial layer, i.e., a doped SEG SiP, formed by selective epitaxial growth (SEG).

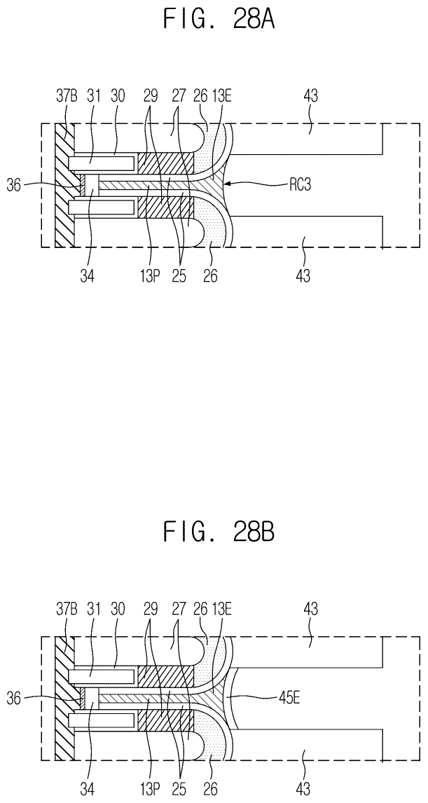

Referring to FIG. 28A, subsequently to FIGS. 19A and 19B, storage openings 44 and wide sheets 13E may be formed by the horizontal recessing of the recessed body portions 13S. In order to form the wide sheets 13E, the recessed body portions 13S may be deeply recessed to expose boundary portions between the nano sheet dielectric layers 25 and the third inter-cell dielectric layers 43. The side surfaces of the wide sheets 13E exposed by the storage openings 44 may each have a rounded concave shape RC3.

Referring to FIG. 28B, a second contact node 45E may be formed along the profile of the rounded concave shape RC3 of each of the wide sheets 13E. Forming the second contact node 45E may include selective epitaxial growth (SEG). For example, a semiconductor material may be grown from the side surface of the wide sheet 13E through the selective epitaxial growth (SEG). The second contact node 45E may include SEG Si. The second contact node 45E may include a dopant. Accordingly, the second contact node 45E may be a doped epitaxial layer. The second contact node 45E may include an N-type dopant as the dopant. The N-type dopant may include phosphorus, arsenic, antimony, or a combination thereof. The second contact node 45E may include a phosphorus-doped silicon epitaxial layer, i.e., a doped SEG SiP, formed by selective epitaxial growth (SEG).

Subsequently to FIGS. 24A to 28B, respective data storage elements CAP may be formed as described with reference to FIGS. 22A to 23B.

According to the above-described embodiments, since the second contact nodes 45A, 45B, 45C, 45D, and 45E each have the rounded concave shape, the rounded convex shape, the angled concave shape, or the angled convex shape, a contact area between each of the second contact nodes 45A, 45B, 45C, 45D, and 45E and the wide sheet 13E may increase, which makes it possible to improve contact resistance.

As a comparative example, the deposition of doped polysilicon, the deposition of a sacrificial material, the recessing process of the doped polysilicon, and the removal process of the sacrificial material may be performed to form second contact nodes 45, 45A, 45B, 45C, 45D, and 45E. However, according to the comparative example, a void may occur during the deposition of the sacrificial material, and accordingly, the doped polysilicon may be all removed during the recessing process so that the second contact nodes may not be formed. In addition, dispersion may occur due to thickness variation during the deposition of the doped polysilicon and recess amount variation of the recessing process of the doped polysilicon. The void, thickness variation and recess amount variation as described above may cause dispersion in electrical characteristics of memory cells, characteristics of cell transistors, and capacitance of data storage elements.

In contrast, according to the above-described embodiments, since the second contact nodes 45, 45A, 45B, 45C, 45D, and 45E are formed through the selective epitaxial growth, process simplification and process stability may be secured to form a data storage element of a three-dimensional memory cell. In addition, the structural dispersion of the three-dimensional memory cell may be improved through the process simplification, and the stability of electrical characteristics may be improved through the improvement of the structural dispersion.

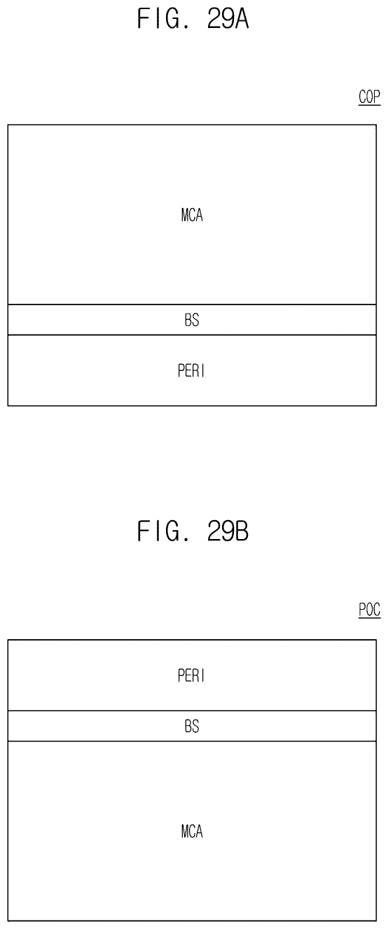

FIGS. 29A and 29B are schematic cross-sectional views illustrating a semiconductor device in accordance with embodiments of the present disclosure.

Referring to FIG. 29A, a semiconductor device COP may include a memory cell array MCA, a peripheral circuit portion PERI, and a bonding interface BS. The bonding interface BS may be disposed between the memory cell array MCA and the peripheral circuit portion PERI. In the semiconductor device COP, the memory cell array MCA may be disposed at a higher level than the peripheral circuit portion PERI. The semiconductor device COP may be referred to as a “Peri Under Cell array (PUC) structure”. The memory cell array MCA may include a substrate on which back grinding is performed and an array of memory cells. For example, as illustrated in FIG. 23B, after the data storage element CAP is formed, the substrate 11 may be flipped over through a wafer flip, and then the substrate 11 may be partially ground back.

Referring to FIG. 29B, a semiconductor device POC may include a memory cell array MCA, a peripheral circuit portion PERI, and a bonding interface BS. The bonding interface BS may be disposed between the memory cell array MCA and the peripheral circuit portion PERI. In the semiconductor device POC, the memory cell array MCA may be disposed at a lower level than the peripheral circuit portion PERI. The semiconductor device POC may be referred to as a Cell array Under Peri (CUP) structure. Forming the peripheral circuit portion PERI may include forming a plurality of control circuits on a peripheral circuit substrate and forming multi-level interconnection on the control circuits.

In FIG. 29A and FIG. 29B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device COP illustrated in FIG. 29A may perform the wafer flip on the substrate on which the memory cell array is formed so that the cell bonding pad and the peripheral circuit bonding pad face each other, after the cell bonding pad and the peripheral circuit bonding pad are formed. The semiconductor device POC illustrated in FIG. 29B may perform the wafer flip on the substrate on which the peripheral circuit portion is formed so that the cell bonding pad and the peripheral circuit bonding pad face each other, after the cell bonding pad and the peripheral circuit bonding pad are formed.

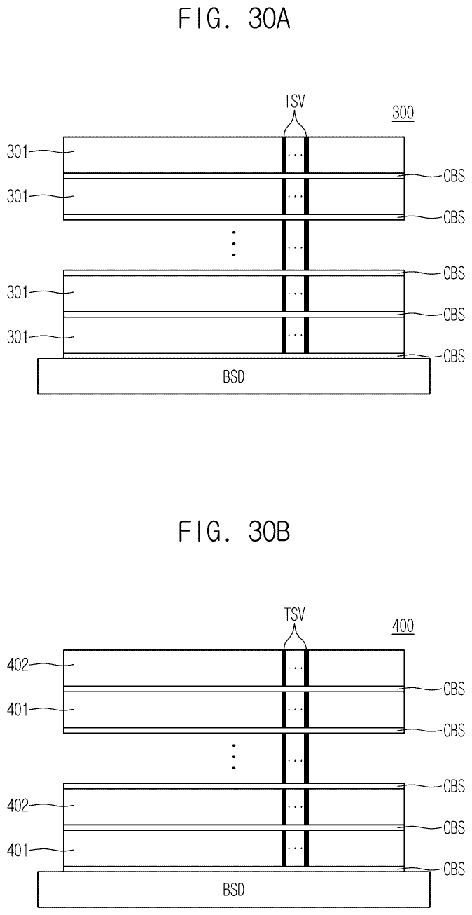

FIGS. 30A and 30B illustrate various views illustrating a stack assembly in accordance with an embodiment of the present disclosure.

Referring to FIG. 30A, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to the embodiments described above. Each of the second semiconductor dies 301 may include structures in which a memory cell array and a peripheral circuit portion are stacked, for example, the semiconductor device COP illustrated in FIG. 29A or the semiconductor device POC illustrated in FIG. 29B. The logic circuits of the first semiconductor die BSD may be different from the peripheral circuit portions of the second semiconductor dies 301. The second semiconductor dies 301 may be chip level or wafer level. The second semiconductor dies 301 may be electrically coupled to each other through a through silicon via TSV and a bonding interface CBS. The first semiconductor die BSD and the second semiconductor die 301 at the lowermost level may be electrically coupled to each other through the bonding interface CBS. The second semiconductor dies 301 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, the second semiconductor dies 301 may be wafer-flipped and ground back to form the bonding interface CBS.

Referring to FIG. 30B, a stack assembly 400 may include an assembly of semiconductor dies. For example, the stack assembly 400 may include a first semiconductor die BSD, a plurality of second semiconductor dies 401, and a plurality of third semiconductor dies 402. The first semiconductor die BSD may include logic circuits. Each of the second semiconductor dies 401 and each of the third semiconductor dies 402 may include memory cell arrays according to the embodiments described above. The second semiconductor dies 401 and the third semiconductor dies 402 may have different structures.

Each of the second semiconductor dies 401 may include structures in which a memory cell array and a peripheral circuit portion are stacked, for example, the semiconductor device COP illustrated in FIG. 29A. Each of the third semiconductor dies 402 may include structures in which a memory cell array and a peripheral circuit portion are stacked, for example, the semiconductor device POC illustrated in FIG. 29B.

In some embodiments, each of the second semiconductor dies 401 may include the semiconductor device POC illustrated in FIG. 29B, and each of the third semiconductor dies 402 may include the semiconductor device COP illustrated in FIG. 29A.

The logic circuits of the first semiconductor die BSD may be different from the peripheral circuit portions of the second and third semiconductor dies 401 and 402. The second and third semiconductor dies 401 and 402 may be chip level or wafer level. The second and third semiconductor dies 401 and 402 may be electrically coupled to each other through a through silicon via TSV and a bonding interface CBS. The first semiconductor die BSD and the second semiconductor die 401 at the lowermost level may be electrically coupled to each other through the bonding interface CBS. The second and third semiconductor dies 401 and 402 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, wafer-flip and back grinding may be performed to form the bonding interface CBS. For example, the second semiconductor dies 401 and/or the third semiconductor dies 402 may be wafer-flipped and ground back.

The stack assemblies 300 and 400 illustrated in FIGS. 30A and 30B may be high bandwidth memories.

According to various embodiments of the present disclosure, since contact nodes are formed using selective epitaxial growth (SEG), void-free contact nodes or seam-free contact nodes may be formed.

According to various embodiments of the present disclosure, since contact nodes are formed using selective epitaxial growth (SEG), the process for forming the contact nodes may be simplified.

While the embodiments of the present disclosure have been illustrated and described with respect to specific embodiments and drawings, the disclosed embodiments are not intended to be restrictive. Further, it is noted that the embodiments of the present disclosure may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor device comprising:
a first conductive line vertically oriented in a first direction;
a data storage element horizontally spaced apart from the first conductive line;
a nano sheet horizontally oriented in a second direction perpendicular to the first direction, and including a first sheet region contacting the first conductive line and a second sheet region contacting the data storage element, which has a thickness gradually increasing from the first sheet region toward the data storage element; and
a second conductive line extending while surrounding the nano sheet in a third direction perpendicular to the first and second directions.

2. The semiconductor device of claim 1, wherein a thickness of the first sheet region in the first direction is less than a thickness of the second sheet region in the first direction.

3. The semiconductor device of claim 1, wherein a length of the first sheet region in the second direction is greater than a length of the second sheet region in the second direction.

4. The semiconductor device of claim 1, wherein the nano sheet further includes first and second doped regions spaced apart from each other in the second direction, and a channel between the first doped region and the second doped region, and
wherein the first doped region and the channel are disposed in the first sheet region, and the second doped region is disposed in the second sheet region.

5. The semiconductor device of claim 1, further comprising:
a first contact node between the first sheet region and the first conductive line; and
a second contact node between the second sheet region and the data storage element.

6. The semiconductor device of claim 5, wherein the second contact node includes a selective epitaxial growth layer.

7. The semiconductor device of claim 5, wherein the second contact node includes a phosphorus-doped silicon epitaxial layer.

8. The semiconductor device of claim 5, wherein a contact surface of the second sheet region and the second contact node includes at least one of a flat shape, a rounded concave shape, an angled concave shape, a rounded convex shape, and an angled convex shape.

9. The semiconductor device of claim 5, wherein each of the first and second contact nodes includes a selective epitaxial growth layer.

10. A semiconductor device comprising:
a first conductive line vertically oriented in a first direction;
a data storage element horizontally spaced apart from the first conductive line;
a nano sheet horizontally oriented in a second direction perpendicular to the first direction, and including a first doped region, a second doped region, and a channel between the first doped region and the second doped region, the first doped region contacting the first conductive line, the second doped region contacting the data storage element and having a thickness gradually increasing from the first doped region toward the data storage element; and
a second conductive line extending while surrounding the channel of the nano sheet in a third direction perpendicular to the first and second directions.

11. The semiconductor device of claim 10, wherein thicknesses of the first doped region and the channel in the first direction are less than a thickness of the second doped region in the first direction.

12. The semiconductor device of claim 10, wherein the nano sheet includes:
a flat plate-shaped sheet in which the first doped region and the channel are disposed; and
a fan-shaped sheet in which the second doped region is disposed.

13. The semiconductor device of claim 10, further comprising:
a first contact node between the first doped region and the first conductive line; and
a second contact node between the second doped region and the data storage element.

14. The semiconductor device of claim 13, wherein the second contact node includes a selective epitaxial growth layer.

15. The semiconductor device of claim 14, wherein the second contact node includes a phosphorus-doped silicon epitaxial layer.

16. The semiconductor device of claim 13, wherein a contact surface of the second doped region and the second contact node includes at least one of a flat shape, a rounded concave shape, an angled concave shape, a rounded convex shape, and an angled convex shape.

17. The semiconductor device of claim 13, wherein each of the first and second contact nodes includes a selective epitaxial growth layer.

18. The semiconductor device of claim 10, wherein the nano sheet includes monocrystalline silicon, an oxide semiconductor material, a two-dimensional material, or a combination thereof.

19. A method for fabricating a semiconductor device, the method comprising:
forming nano sheet target layers over a substrate, the nano sheet target layers vertically stacked and spaced apart from each other;
forming flat plate-shaped sheets that trim first portions of the nano sheet target layers;
horizontally recessing second portions of the nano sheet target layers to form fan-shaped sheets;
selectively growing contact nodes on side surfaces of the fan-shaped sheets; and
forming data storage elements coupled to the contact nodes.

20. The method of claim 19, wherein selectively growing the contact nodes on the side surfaces of the fan-shaped sheets includes growing a doped silicon layer on the side surfaces of the fan-shaped sheets through selective epitaxial growth.

21. The method of claim 19, wherein the doped silicon layer includes a phosphorus-doped silicon layer.

22. The method of claim 19, wherein each of the nano sheet target layers includes monocrystalline silicon.

23. The method of claim 19, further comprising:
forming horizontal conductive lines extending while surrounding the flat plate-shaped sheets disposed at a horizontal level; and
forming a vertical conductive line coupled in common to the flat plate-shaped sheets.
